(19) United States
(12) Patent Application Publication
(10) Pub. No.: US 2011/0245429 A1
(43) Pub. Date: Oct. 6, 2011

(54) Cross Linked Organic Conductive Layer

(76) Inventors: Neil Gough, Kingston Upon Hull (GB); Ethan Tsai, Boulder, CO (US)

(21) Appl. No.: 13/139,219

(22) PCT Filed: Dec. 10, 2008
(86) PCT No.: PCT/US08/86250

§ 371 Date: Jun. 10, 2011

(51) Int. Cl. C08F 226/06; C07D 209/82

(52) U.S. Cl. 525/304; 438/22; 548/440; 526/259; 257/E33.063

(57) ABSTRACT

The present invention provides various compounds, compositions, methods, and processes for forming a cross-linked conductive polymeric layer in an electronic device.

### FIELD OF THE INVENTION

The present invention relates to various compounds, compositions, methods, and processes for forming a cross-linked conductive polymeric layer in an electronic device.

### BACKGROUND OF THE INVENTION

The operation of an organic light emitting diode (OLED) can be either electroluminescent or electro-phosphorescent in nature. In each case, semi-conducting organic materials are sandwiched between two electrodes. During operation, charge is injected from the electrodes into the organic layers, followed by charge migration within the layers. Electrons and holes (deficient electrons) combine to form an excited singlet or triplet state, and relaxation of this excited state results in light emission.

In order to achieve a relatively high efficiency and a long life time, the material needs to fulfill several requirements: a low injection barrier at the electrode and organic material interface, balanced electron/hole density and mobility and in the case of an OLED device, a high quantum efficiency (e.g., number of photons emitted for each electron injected). Furthermore, the recombination site for electrons and holes in an OLED device should be located away from the metal cathode to prevent ‘quenching’ of the injected charges. The materials used in the construction of the device also need to be thermally stable in order to avoid thermal degradation during processing and subsequent operation. As a consequence of these demands, a ‘stack’ of different materials are used. A typical OLED consists of a transparent substrate comprising either glass or PET, an anode, which is commonly indium-tin-oxide (ITO) and a metal cathode. Suitable metals for the cathode include, but are not limited to, Mg, Ca, Al, Ag and alloys of selected metals. Between the two electrodes a stack of organic layers are deposited that perform various tasks including charge injection, transport and emission.

Because of the usefulness and the potential that OLED devices possess, a good deal of effort has been made in the development of the OLED materials and the process with which the various layers are fabricated. The organic materials used in an OLED stack are designed to achieve desired optoelectronic properties and process characteristics. Some degree of success has been achieved by the manipulation of the chemical structure of the respective materials, resulting in the development of a large number of materials in recent years. The most effective hole-transport or electron blocking materials developed to date have been found to be triarylamine and pyrazoline derivatives. Compounds that are electron deficient have been found to be most effective in terms of their electron-transport or hole-blocking functionality, resulting in the development of a very large number of available compounds, the most effective compounds to date being 1,3,4-oxadiazoles, 1,2,4-triazoles, 1,3-oxazoles, pyridines, quinoxalines, and the most commonly used of which being the aluminum derived complex known as Alq3. These materials are generally referred to as being ‘small molecules’, conversely, highly conjugated polymers such as poly(arylene)s, poly(phenylenevinylene)s, poly(fluorene)s, are also effective OLED device materials.

Some of the exemplary small molecule hole-transport materials include the following compounds:

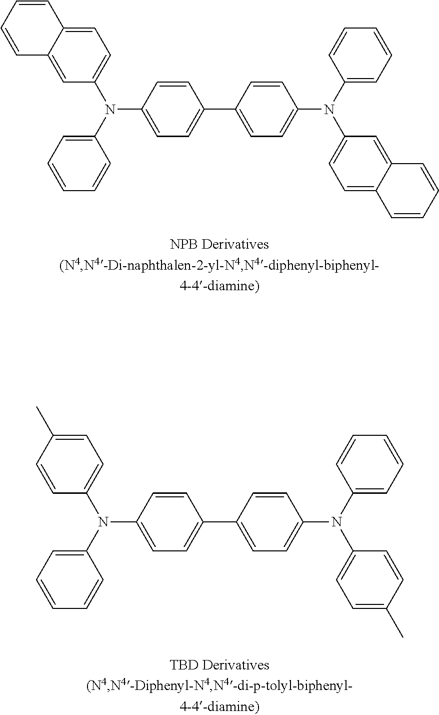

Some of the exemplary small molecule electron-transport materials include the following compounds:

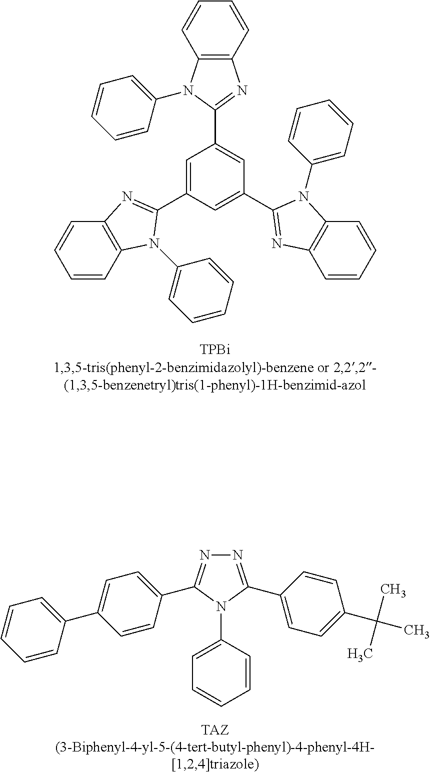

Exemplary small molecule emitters include the following compounds:

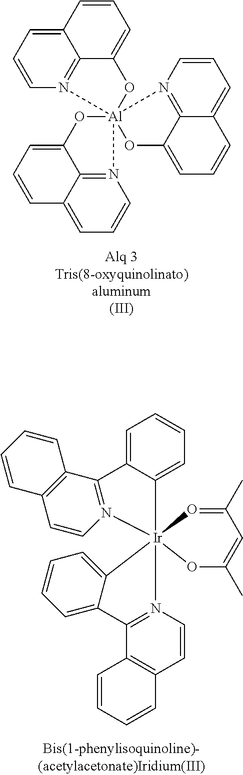

Exemplary hole-injection polymer materials include the following polymers:

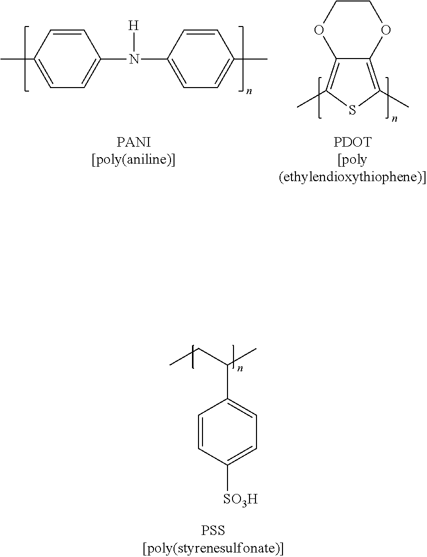

Exemplary electron-injection/transport polymer materials include the following polymers:

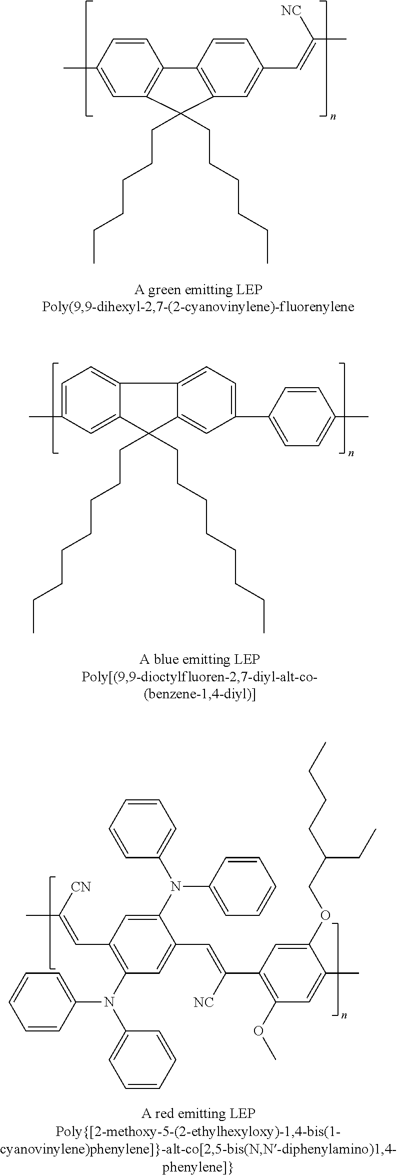

Two often utilized processes in the construction of an OLED device include sublimation or organic vapor deposition (OVD) and solution processing. OVD refers to the deposition of the organic layers via vapor deposition of the compound from the solid state. Vapor deposition generally results in a well defined layer possessing excellent purity; however this methodology is typically applicable to only low molecular weight molecules possessing high thermal stability. Solution processing, such as spin coating or printing methods require materials or precursors that are soluble in a suitable solvent. This method is widely used in combination with polymers and dendrimers and provides for a layer structure possessing a high degree of homogeneity and potentially offers a reduction in manufacturing costs when compared to OVD methodologies. One of the main disadvantages of solution based processing is the possibility of altering or damaging the already fabricated layer by the solvent used in either printing or spin coating subsequent layers.

Therefore, there is a need for methods to prevent the possibility of damaging the already fabricated layers when spin coating or printing the next layer.

### SUMMARY OF THE INVENTION

The present invention provides various compounds, compositions, methods, and processes for reducing the possibility of or preventing damaging already fabricated layer during spin coating or printing of the next layer in an electronic device. Some aspects of the invention provide compounds, compositions, processes and methods that cross-link the fabricated layer to prevent them from being damaged by a subsequent processing step. Cross-linking can be achieved by any of the methods known to one skilled in the art including, but not limited to, using a thermal, chemical, and/or photo-induced cross-linking processes.

Some aspects of the invention provide an electronic device comprising an organic conductive layer, where the organic conductive layer comprises a cross-linked polymer of a conductive material. In some embodiments, the electronic device is an organic light emitting diode (OLED). Within these embodiments, in some instances, the OLED is an electroluminescent OLED or an electro-phosphorescent OLED. Yet in other embodiments, the conductive layer is a hole-transport layer or an electron-transport layer of OLED.

Other aspects of the invention provide a method for producing an organic conductive layer in an electronic device. The method typically comprises:
attaching a layer of organic conductive material onto a solid substrate, wherein the organic conductive material comprises an electric conducting moiety and a cross-linkable moiety; and
cross-linking the organic conductive material to one another by subjecting the solid substrate bound organic conductive material to conditions sufficient to form cross-linkage between the solid substrate bound organic conductive materials.

In some embodiments, the electronic device is an organic light emitting diode (OLED). Within these embodiments, in some instances the organic conductive layer is a hole-transport layer or an electron-transport layer.

Yet in other embodiments, the cross-linkable moiety comprises a diene, siloxane, acylate, styrene, epoxide, trifluorovinyloxy, acrylate, methacrylate, or oxetane moiety.

Still in some embodiments, the step of cross-linking comprises thermal annealing, photolysis, reacting the solid substrate bound organic conductive material with a cross-linking compound, or a combination thereof.

Yet other aspects of the invention provide, a compound of the formula:

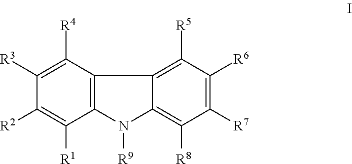

where
each of R¹, R², R⁴, R⁵, R⁷, and R⁸ is independently, hydrogen, alkyl, halide, nitro, cyano, —Y¹R^{a}, —NR^{a}R^{b}, or —C(═O)R^{c},
wherein
   Y¹ is O or S;
   each R^{a} is independently hydrogen, or alkyl;
   each R^{b} is hydrogen, alkyl, or a nitrogen protecting group;
   R^{c} is hydrogen, alkyl, aryl, aralkyl, or haloalkyl;
each of R³ and R⁶ is independently —XAr¹, —NAr¹R¹⁰, or a substituted aryl,
wherein
   X is O or S;
   R¹⁰ is hydrogen, alkyl, or an optionally substituted aryl; and
   Ar¹ is a substituted aryl; and

R⁹ is a substituted aryl group comprising a cross-linkable functional group moiety, provided at least one of the aryl substituent of R³ comprises an electron withdrawing group and at least one of R⁶ or the aryl substituent [e.g., a substituent of Ar¹, R¹⁰ (when R¹⁰ is a substituted aryl), or R^{c} (when R^{c} is aryl or aralkyl)] comprises an electron withdrawing group or a cross-linkable functional group moiety.

In some embodiments, the compound is of the formula:

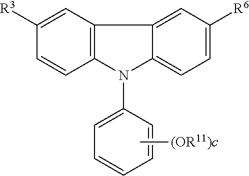

where
c is an integer from 1 to 3;
R³ and R⁶ are as defined above; and
R¹¹ is —R¹²—Z,
where
   R¹² is alkylene; and
   Z is —Y²R^{d}, —NR^{d}R^{e}, or a cross-linkable functional group moiety,
   wherein
      Y² is O or S;
      each R^{d} is independently hydrogen, or alkyl; and
      each R^{e} is hydrogen, alkyl, or a nitrogen protecting group.

Yet in other embodiments, the compound is of the formula:

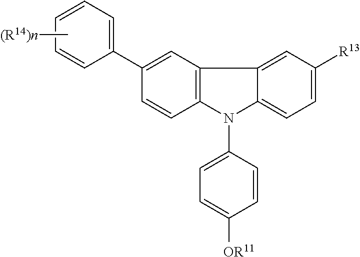

where
R¹¹ is as defined above;

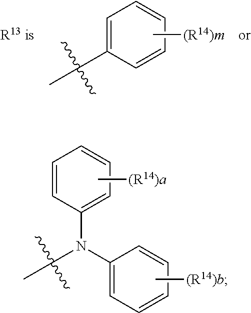

each of a, b, m, and n is independently an integer from 0 to 5; and
each R¹⁴ is independently an electron withdrawing group, or a cross-linkable functional group moiety,
   provided at least one of R¹⁴ is an electron withdrawing group and at least one of R¹¹ and R¹⁴ comprises a cross-linkable functional group moiety.

Still in other embodiments, the compound is of the formula:

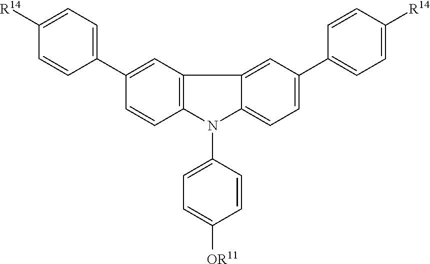

where
R¹¹ is as defined above; and
each R¹⁴ is independently an electron withdrawing group, or a cross-linkable functional group moiety,
   provided at least one of R¹⁴ is an electron withdrawing group and at least one of R¹¹ and R¹⁴ comprises a cross-linkable functional group moiety.

In other embodiments, the compound is of the formula:

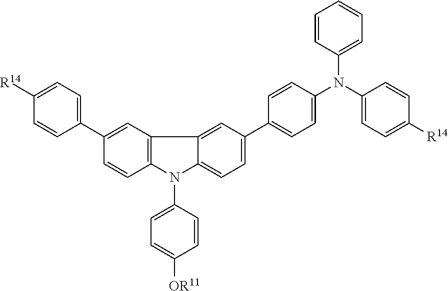

where
R¹¹ is as defined above; and
each R¹⁴ is independently an electron withdrawing group, or a cross-linkable functional group moiety,
   provided at least one of R¹⁴ is an electron withdrawing group and at least one of R¹¹ and R¹⁴ comprises a cross-linkable functional group moiety.

In some embodiments, R¹² is C₂-C₁₂ alkylene.

Still in other embodiments, Z is —OH or a cross-linkable functional group moiety.

Yet still in other embodiments, the cross-linkable functional group moiety comprises a diene, siloxane, acylate, styrene, epoxide, trifluorovinyloxy, acrylate, methacrylate, or oxetane moiety.

Other aspects of the invention provide a conductive polymeric layer in an electronic device, wherein said conductive polymeric layer comprises a cross-linked monomer of a compound of Formula I. In some embodiments, the electronic device is an organic light emitting diode (OLED), a solar energy panel, an organic thin film transistor, or an organic radio frequency identification chip.

In some particular instances, the electronic device is an OLED. Within these instances, in some cases the OLED is a small molecule electroluminescent OLED, a small molecule electro-phosphorescent OLED, a polymer OLED, a quantum dot OLED or a combination thereof. In other cases, the conductive polymeric layer is a hole-transport layer or an electron-transport layer.

### BRIEF DESCRIPTION OF THE DRAWINGS

FIG. 1 is a graph showing film thickness of various polymer films formed by varying the percentage by mass of solids utilizing 5 and 10% relative concentrations of catalyst.

### DETAILED DESCRIPTION OF THE INVENTION

“Alkyl” refers to a saturated linear monovalent hydrocarbon moiety of one to twenty, typically one to twelve and often one to six, carbon atoms or a saturated branched monovalent hydrocarbon moiety of three to twenty, typically three to twelve and often three to six, carbon atoms. Alkyl group can be optionally substituted. When two or more substituents are present in an alkyl group, each substituent is independently selected as long as they do not form an unstable moiety. When an alkyl group is substituted with one or more halide, it can also be referred to as haloalkyl. Exemplary alkyl group include, but are not limited to, methyl, ethyl, n-propyl, 2-propyl, tert-butyl, pentyl, and the like.

“Alkylene” refers to a saturated linear saturated divalent hydrocarbon moiety of one to twenty, typically two to twelve and often two to six, carbon atoms or a branched saturated divalent hydrocarbon moiety of three to twenty, typically three to twelve, carbon atoms. Exemplary alkylene groups include, but are not limited to, methylene, ethylene, propylene, butylene, pentylene, and the like.

“Aryl” refers to a monovalent mono-, bi- or tricyclic aromatic hydrocarbon moiety of 6 to 15 ring atoms which is optionally substituted with one or more, typically one, two, or three substituents within the ring structure. When two or more substituents are present in an aryl group, each substituent is independently selected.

“Aralkyl” refers to a moiety of the formula —R^{b}R^{c} where R^{b} is an alkylene group and R^{c} is an aryl group as defined herein. Exemplary aralkyl groups include, but are not limited to, benzyl, phenylethyl, 3-(3-chlorophenyl)-2-methylpentyl, and the like.

“Cycloalkyl” refers to a non-aromatic, monovalent mono- or bicyclic hydrocarbon moiety of three to ten ring carbons. The cycloalkyl can be optionally substituted with one or more, typically one, two, or three, substituents within the ring structure. When two or more substituents are present in a cycloalkyl group, each substituent is independently selected.

“Cycloalkylalkyl” refers to a moiety of the formula —R^{d}R^{e} where R^{d} is an alkylene group and R^{e} is a cycloalkyl group as defined herein. Exemplary cycloalkylalkyl groups include, but are not limited to, cyclopropylmethyl, cyclohexylpropyl, 3-cyclohexyl-2-methylpropyl, and the like.

“Electron withdrawing group” refers to a moiety that draws electrons away from a reaction center. One skilled in the art can readily recognize that an electron withdrawing group comprises one or more atoms that are higher in electronegativity than the neighboring group. Such groups can be conjugated with an olefin. Exemplary electron withdrawing groups include, but are not limited to, halides (e.g., F, Cl, Br, or I), other electronegative heteroatom (e.g., O, N, S, P, etc.) containing groups, nitriles (—CN); carboxylates (—COOR, where R is typically H or alkyl); carbonyls [C(═O)], nitro, nitroso, etc.

The terms “halo,” “halogen” and “halide” are used interchangeably herein and refer to fluoro, chloro, bromo, or iodo.

“Haloalkyl” refers to an alkyl group as defined herein in which one or more hydrogen atom is replaced by same or different halo atoms. The term “haloalkyl” also includes perhalogenated alkyl groups in which all alkyl hydrogen atoms are replaced by halogen atoms. Exemplary haloalkyl groups include, but are not limited to, —CH₂Cl, —CF₃, —CH₂CF₃, —CH₂CCl₃, and the like.

The term “functional group” in organic chemistry is well recognized by one skilled in the art. An exemplary understanding of the term “functional group” includes referring to one or a group of atoms within a molecule that is responsible for the characteristic chemical reactions of that molecule. The same functional group will generally undergo the same or similar chemical reaction(s). However, its relative reactivity can be modified by nearby functional groups. It should be appreciated that the term “functional group” is used herein to mean the broadest definition known to one skilled in the art of organic chemistry.

“Complementary functional group” is well known to one skilled in the art of organic chemistry. Typically, such a term refers to a functional group that is capable of reacting with a given functional group to form a chemical bond.

When describing a chemical reaction, the terms “treating”, “contacting” and “reacting” are used interchangeably herein, and refer to adding or mixing two or more reagents under appropriate conditions to produce the indicated and/or the desired product. It should be appreciated that the reaction which produces the indicated and/or the desired product may not necessarily result directly from the combination of two reagents which were initially added, i.e., there may be one or more intermediates which are produced in the mixture which ultimately leads to the formation of the indicated and/or the desired product.

As used herein, the terms “as defined above,” “as defined herein,” “those defined above” and “those defined herein” are used interchangeably herein when referring to a variable and incorporates by reference the broad definition or the broad range of the variable as well as any narrow definitions or narrow ranges, if any.

Advancement in organic electronic devices such as OLED and organic photo-voltaic (OPV) devices depends on inter alia development of novel conductive organic materials. For ease of use and cost of production purposes, these organic materials need to be printable materials. The development of conductive main-chain polymers is costly and time consuming. Moreover, these polymers are often difficult to purify and often prove to be problematic during a scale-up effort. Furthermore, it is often difficult to introduce a secondary functional group into main-chain polymers. Therefore, it is generally not possible to change the physical properties of the polymer.

Some aspects of the invention provide materials and methods for producing highly functionalized polymer films that are stable to subsequent solution based process steps.

Other aspects of the invention provide polymeric materials that possess a conductive core. In some embodiments, polymers of the invention include one or more function groups that are selected for either physical or electronic purposes.

### Compounds and Materials of the Invention

Some aspects of the invention provide a compound of the formula:

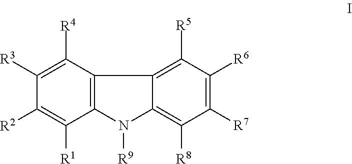

where
each of R¹, R², R⁴, R⁵, R⁷, and R⁸ is independently, hydrogen, alkyl, halide, nitro, cyano, —Y¹R^{a}, —NR^{a}R^{b}, or —C(═O)R^{c},
wherein
   Y¹ is O or S;
   each R^{a} is independently hydrogen, or alkyl;
   each R^{b} is hydrogen, alkyl, or a nitrogen protecting group;
   R^{c} is hydrogen, alkyl, aryl, aralkyl, or haloalkyl;
each of R³ and R⁶ is independently —XAr¹, —NAr¹R¹⁰, or a substituted aryl,
wherein
   X is O or S;
   R¹⁰ is hydrogen, alkyl, or an optionally substituted aryl; and
   Ar¹ is a substituted aryl; and

R⁹ is a substituted aryl group comprising a cross-linkable functional group moiety, provided at least one of the aryl substituent of R³ comprises an electron withdrawing group and at least one of the aryl substituent or R⁶ comprises an electron withdrawing group or a cross-linkable functional group moiety.

In some embodiments, compounds of the invention is of the formula:

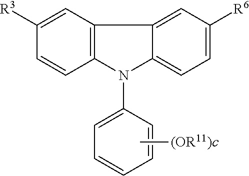

where
c is an integer from 1 to 3;
R³ and R⁶ are those defined herein; and
R¹¹ is —R¹²—Z,
where
   R¹² is alkylene; and
   Z is —Y²R^{d}, —NR^{d}R^{e}, or a cross-linkable functional group moiety,
   where
      Y² is O or S;
      each R^{d} is independently hydrogen, or alkyl; and
      each R^{e} is hydrogen, alkyl, or a nitrogen protecting group.

Within these embodiments, in some instances compounds of the invention are of the formula:

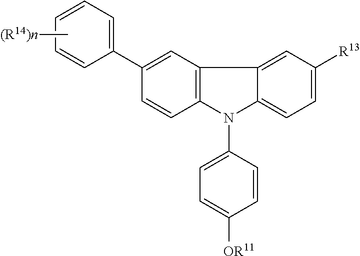

where
R¹¹ is those defined herein

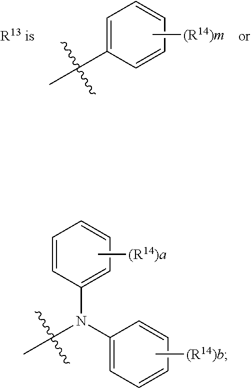

each of a, b, m, and n is independently an integer from 0 to 5;
each R¹⁴ is independently an electron withdrawing group, or a cross-linkable functional group moiety,
   provided at least one of R¹⁴ is an electron withdrawing group and at least one of R¹¹ and R¹⁴ comprises a cross-linkable functional group moiety.

Within these instances, in some cases compounds of the invention are of the formula:

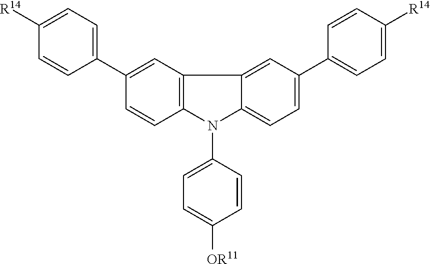

where
R¹¹ is those defined herein; and
each R¹⁴ is independently an electron withdrawing group, or a cross-linkable functional group moiety,
   provided at least one of R¹⁴ is an electron withdrawing group and at least one of R¹¹ and R¹⁴ comprises a cross-linkable functional group moiety.

In other cases, compounds of the invention are of the formula:

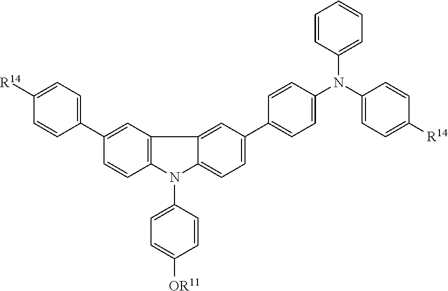

where
R¹¹ is those defined herein; and
each R¹⁴ is independently an electron withdrawing group, or a cross-linkable functional group moiety,
   provided at least one of R¹⁴ is an electron withdrawing group and at least one of R¹¹ and R¹⁴ comprises a cross-linkable functional group moiety.

In some embodiments, R¹² is C₂-C₁₂ alkylene.

In other embodiments, Z is —OH or a cross-linkable functional group moiety. In some cases, the cross-linkable functional group moiety comprises a polyene such as a diene (typically a conjugated diene), siloxane, acylate (e.g., —OC(═O)CH₃, styrene, epoxide, trifluorovinyloxy (i.e., —OCF═CF₂), acrylate (i.e., —OC(═O)CH═CH₂), methacrylate (i.e., —OC(═O)C(CH₃)═CH₂), or oxetane moiety. It should be appreciated that the cross-linkable functional group can include a linker that connects the “core” compounds to the cross-linkable functional group. Typically, the cross-linkable functional group moiety comprises an alkylene chain that serves as a linker connecting the cross-linkable functional group to the core structure.

Still further, combinations of various groups described herein form other embodiments. In this manner, a wide variety of compounds are embodied within the present invention.

### Synthesis

Scheme 1 provides one particular example of reactions and reagents that can be used in preparing a compound of the invention having a carbazole core. The compound has been modified by incorporating an electron withdrawing group (i.e., di-cyanovinyl moieties) to modify the electronic property, while the cross-linking group (i.e., polymerization moiety) is in the form of a 2-methyl-acryloyloxy, which is attached to the core by an alkyloxy spacer.

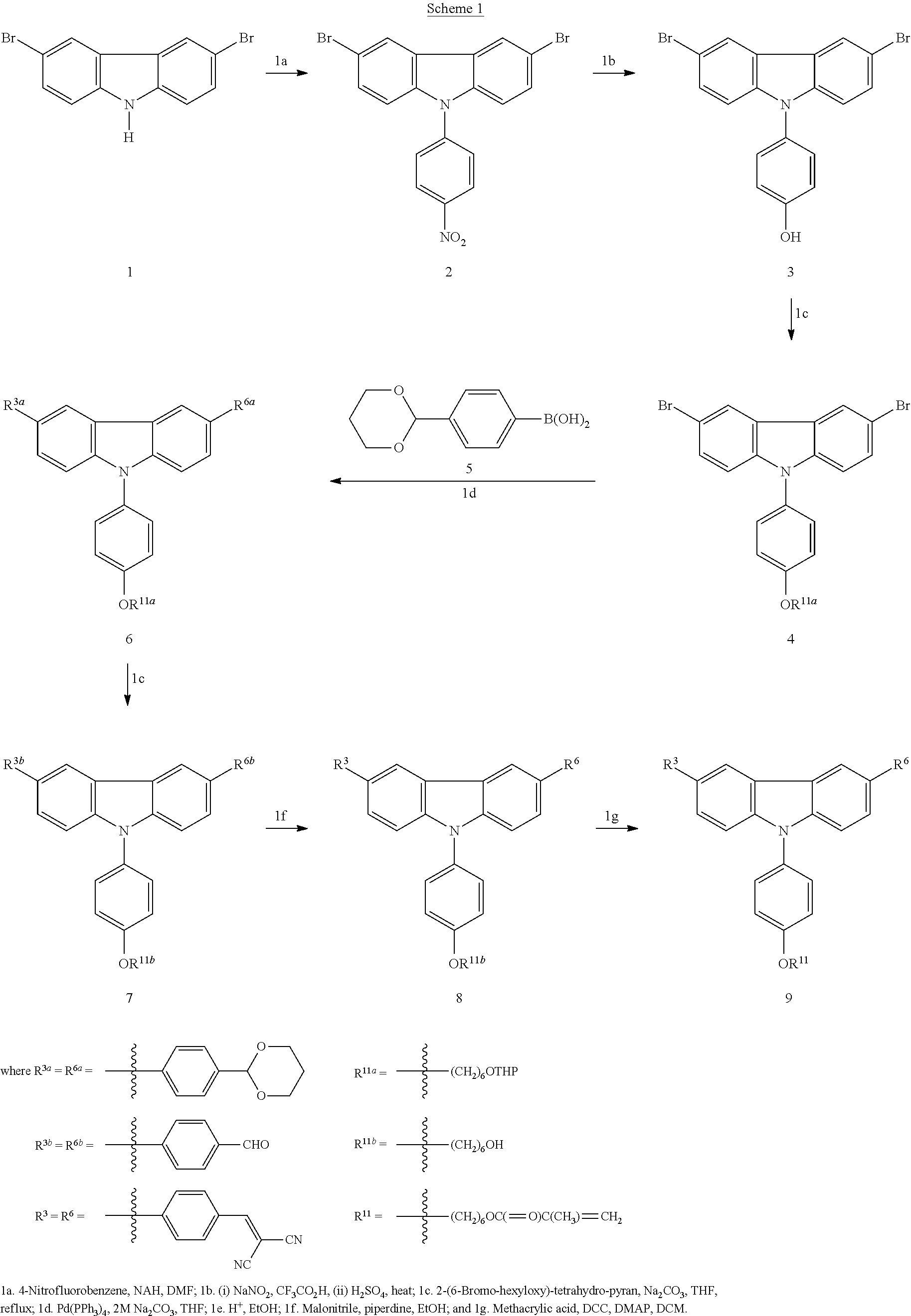

Scheme 2 provides another reaction scheme for reactions and reagents that can be used in preparing a compound of the invention having a vinylcyano moiety as the electron withdrawing group and a trifluorovinyloxy moiety as a cross-linking functional group.

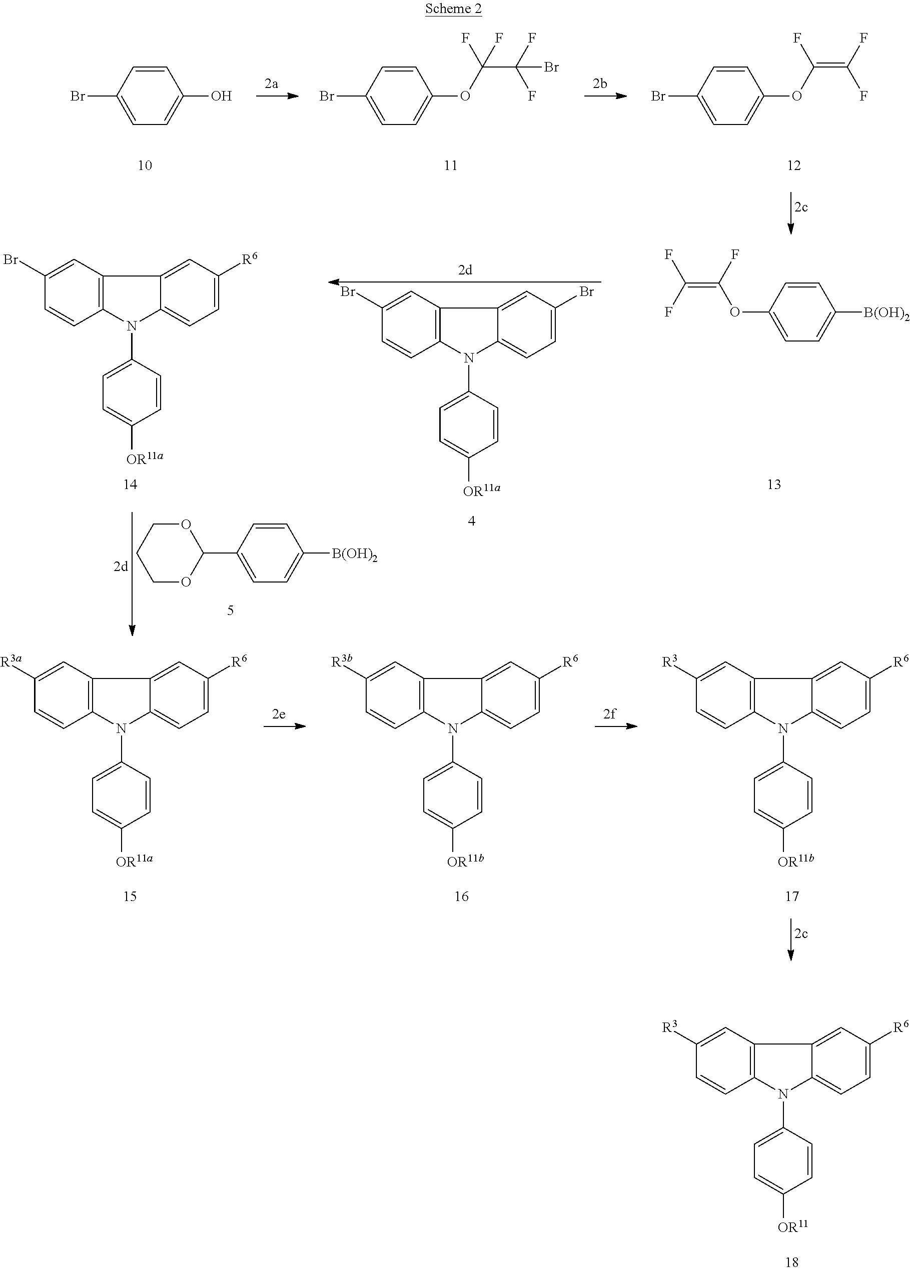

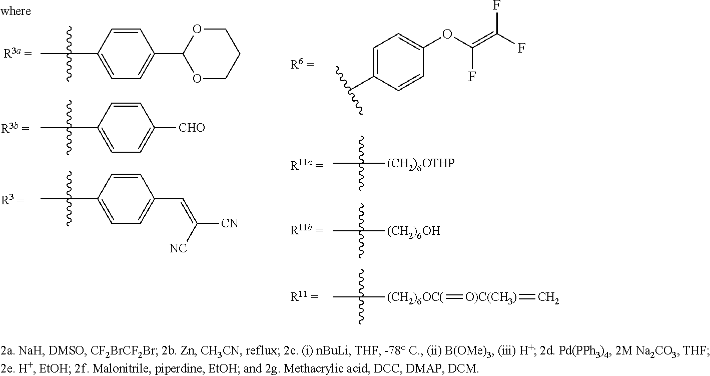

Scheme 3 provides another reaction scheme for reactions and reagents that can be used in preparing for a compound of the invention that is similar to that detailed in Scheme 2 except that the cross-linking functional group trifluorovinyloxy moiety has been replaced with a different cross-linking functional group (e.g., an oxetane moiety) that is capable of being cross-linked using a photo-generated acid initiator.

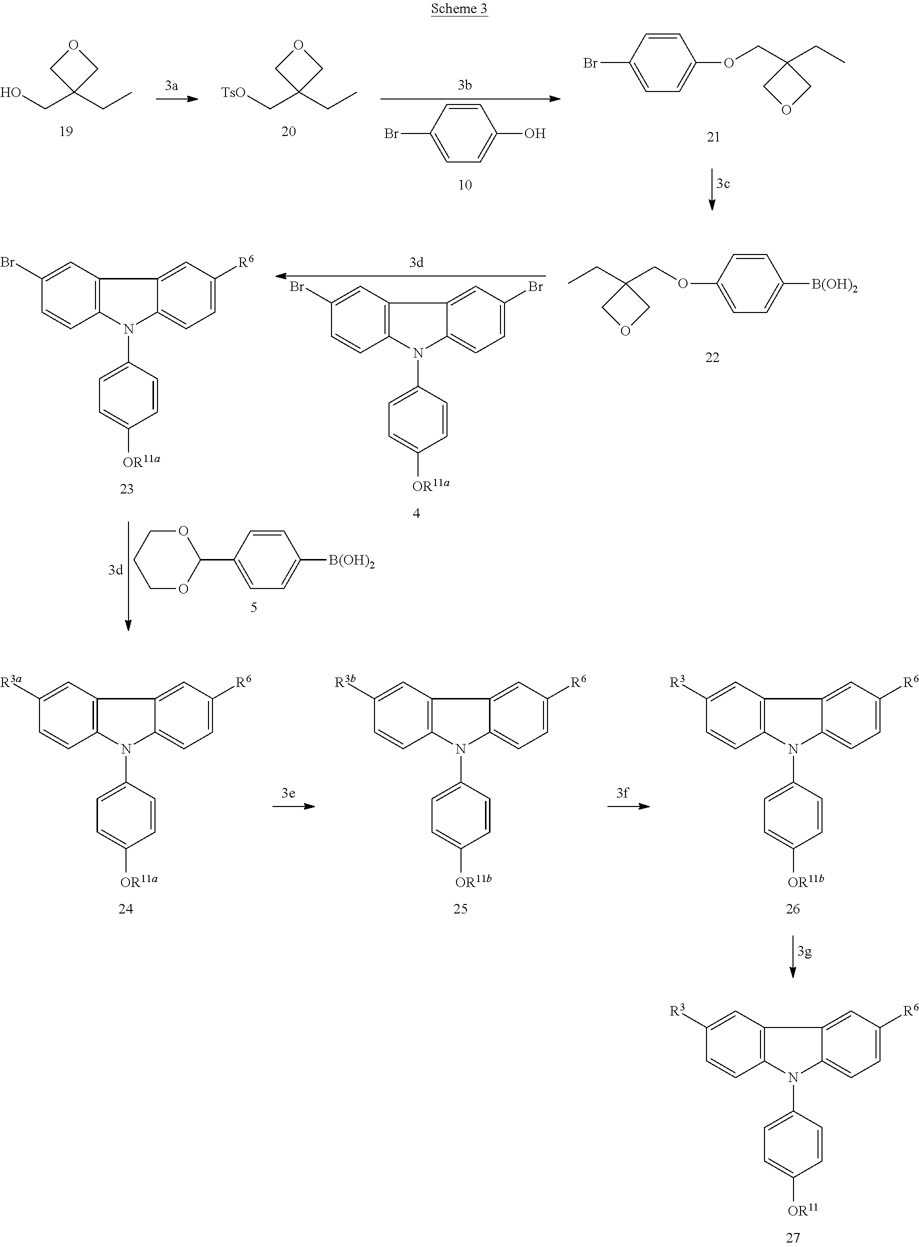

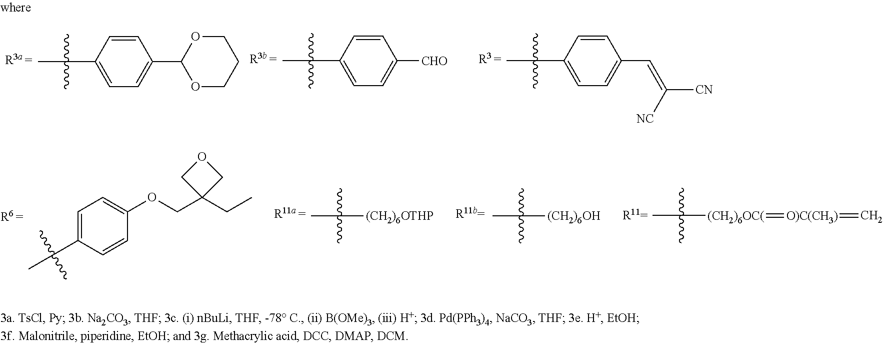

Scheme 4 provides another reaction scheme for reactions and reagents that can be used in preparing for a compound of the invention that is similar to those described in Schemes 1-3 above except that the cross-linking functional group is a styrene moiety.

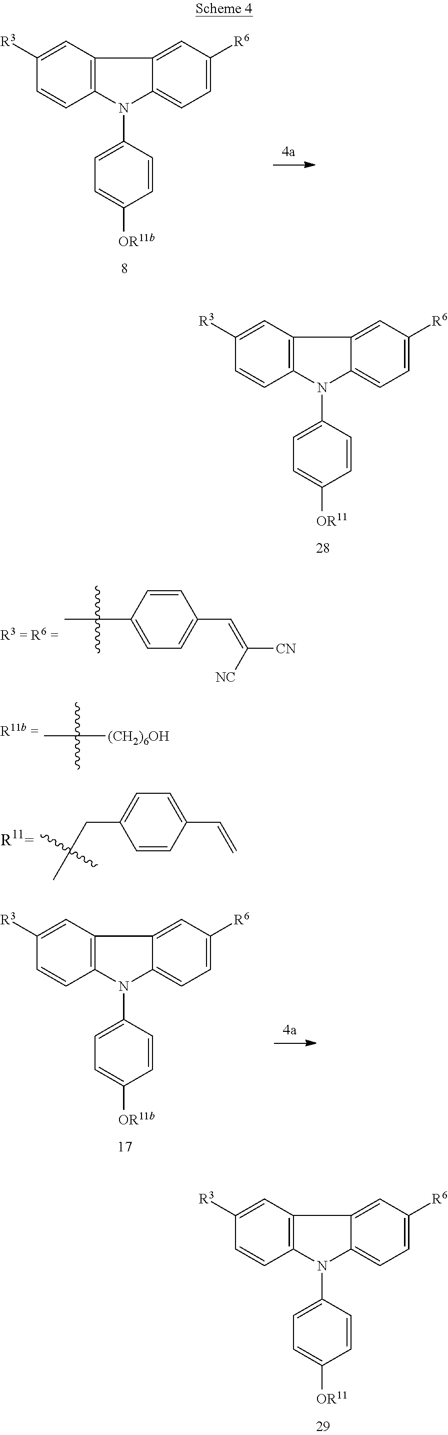

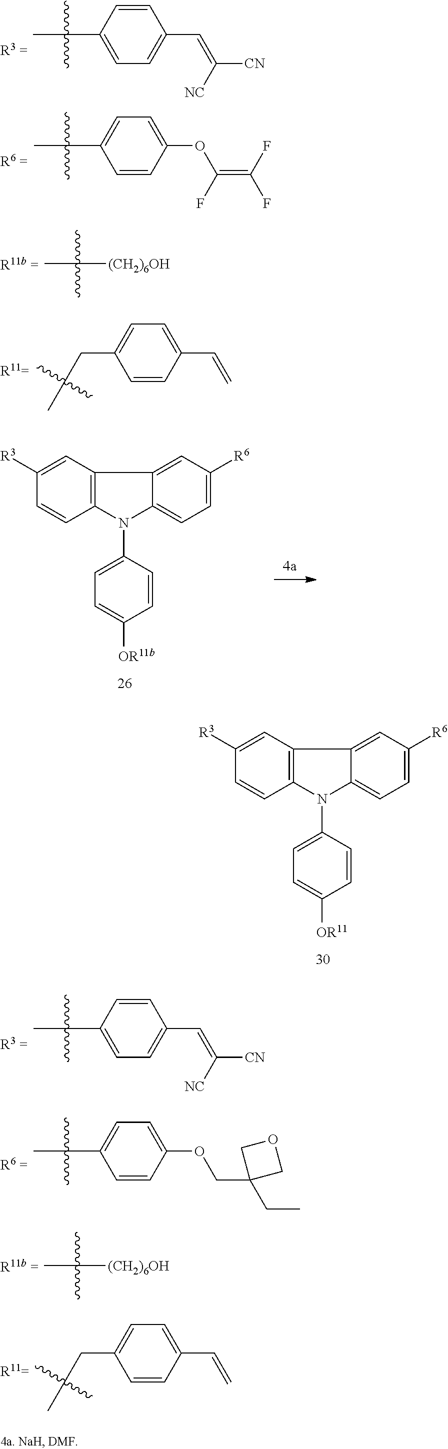

Scheme 5 provides another reaction scheme for reactions and reagents that can be used in preparing for a compound of the invention. In this example, compounds of the invention comprise a conductive core that is substituted with a biphenyl amine moiety having a cross-linking group and a phenyl moiety having a dicyanovinyl electron withdrawing group.

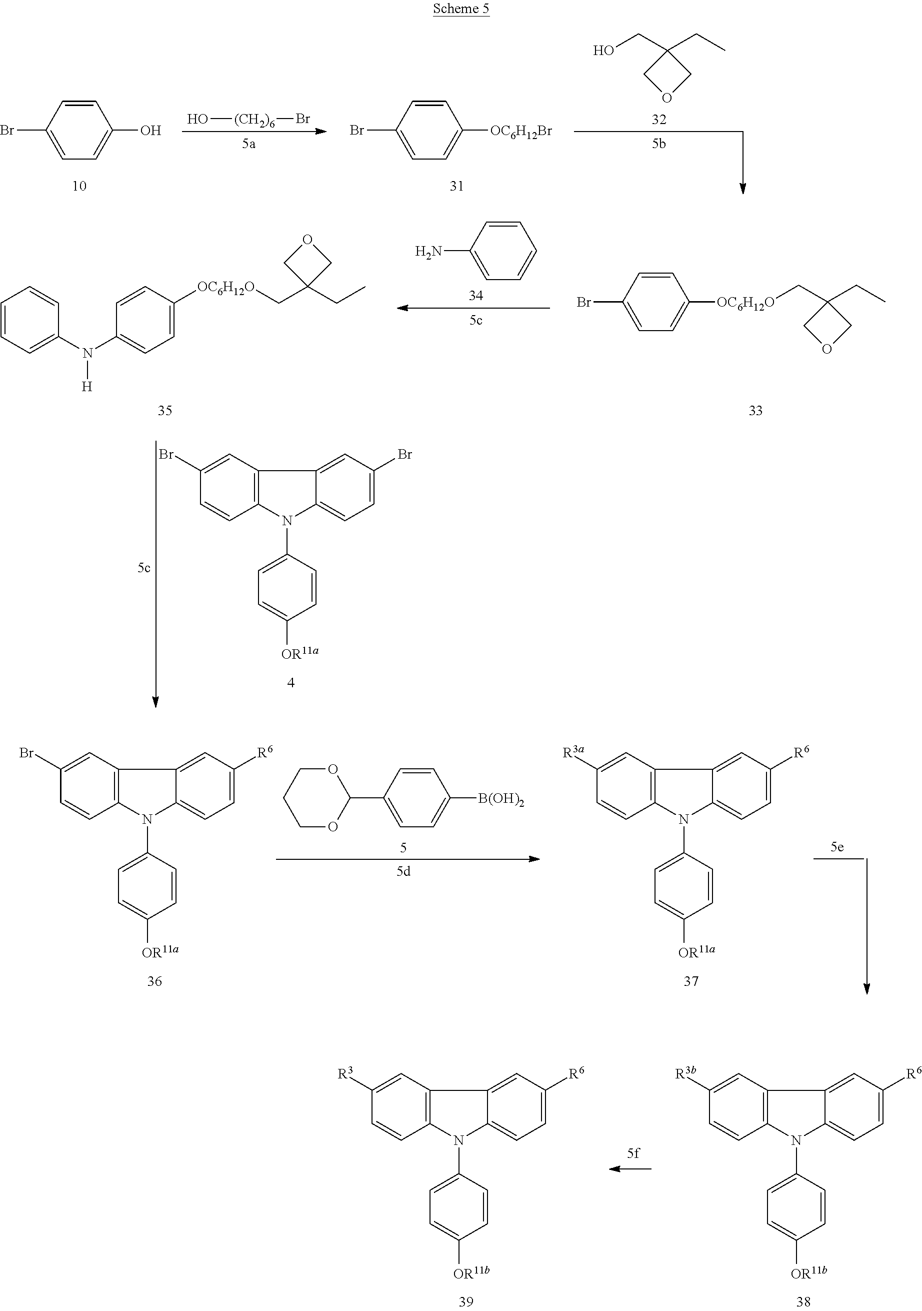

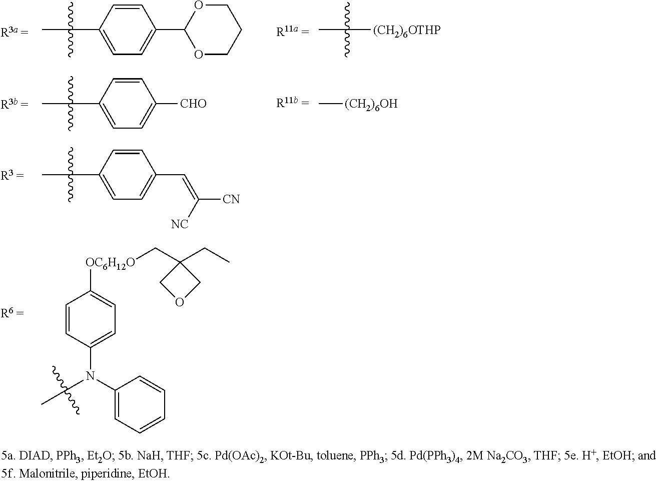

Scheme 6 illustrates reaction scheme for reactions and reagents that can be used to add different cross-linking functional groups, e.g., 2-methyl-acryloyloxy and styrene moieties.

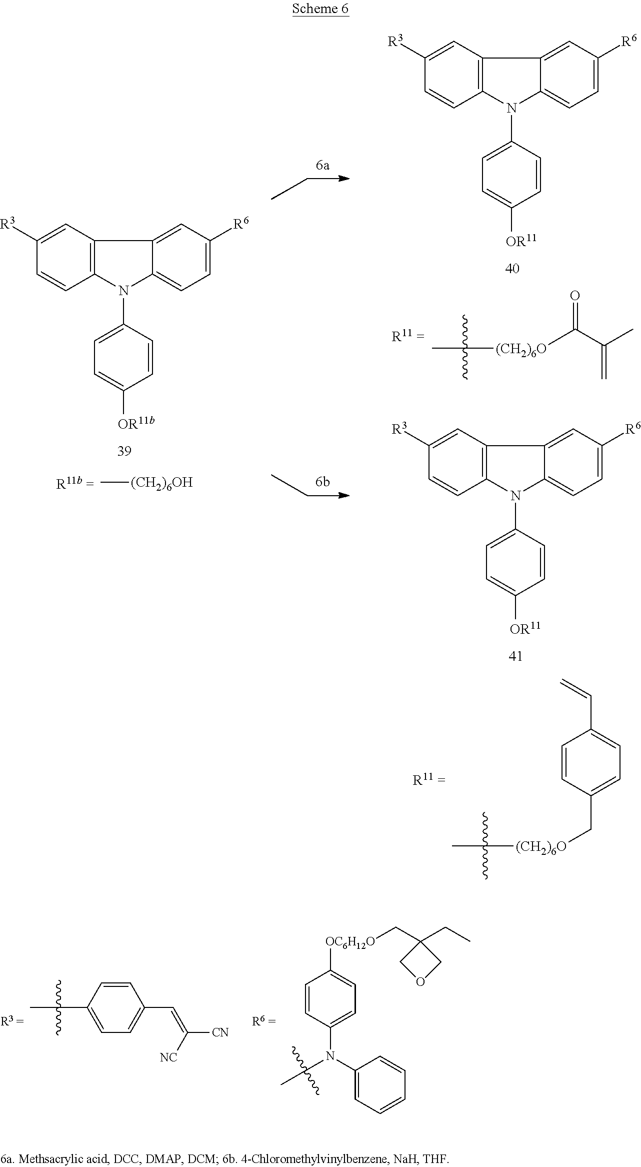

Some aspects of the invention provide compositions comprising a compound of Formula I. In certain embodiments, compositions of the invention can also include other co-monomers. One or more co-monomers can be added to the compositions of the invention to provide polymers with desired solubility, physical and/or electronic properties. There are a wide variety of co-monomers available to achieve various physical and/or electronic properties. Schemes 7, 8 and 9 provide some examples for producing linear co-monomers that could be blended with a compound of the invention to provide various mechanical and/or electronic properties of the resulting polymer.

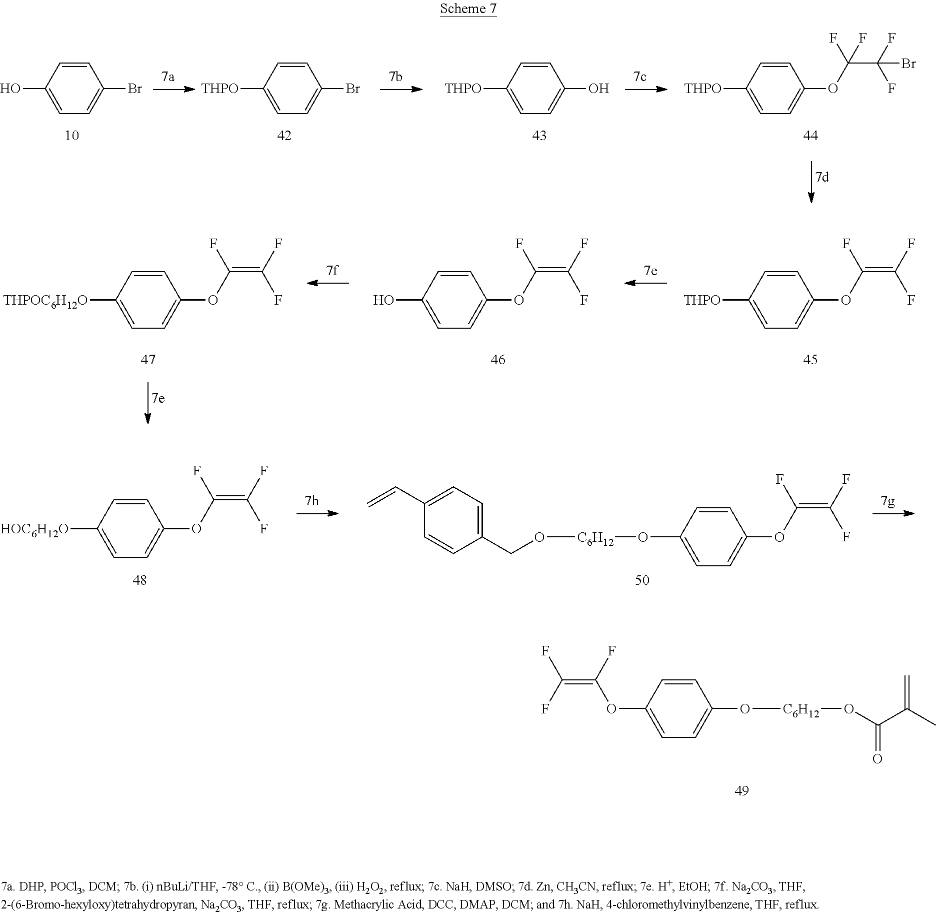

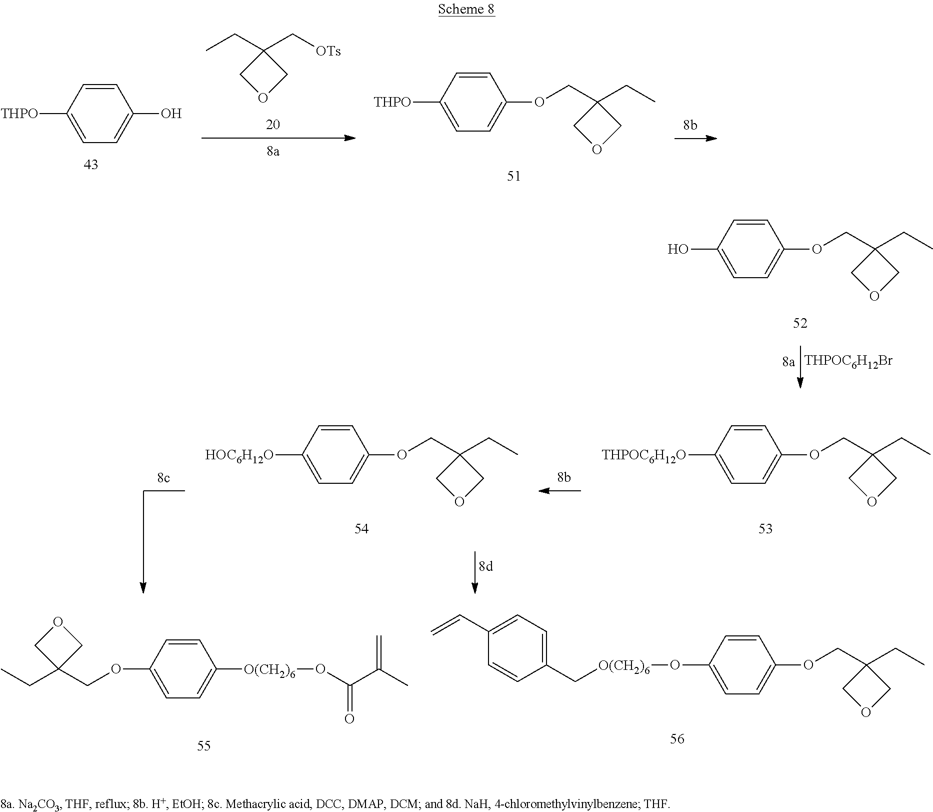

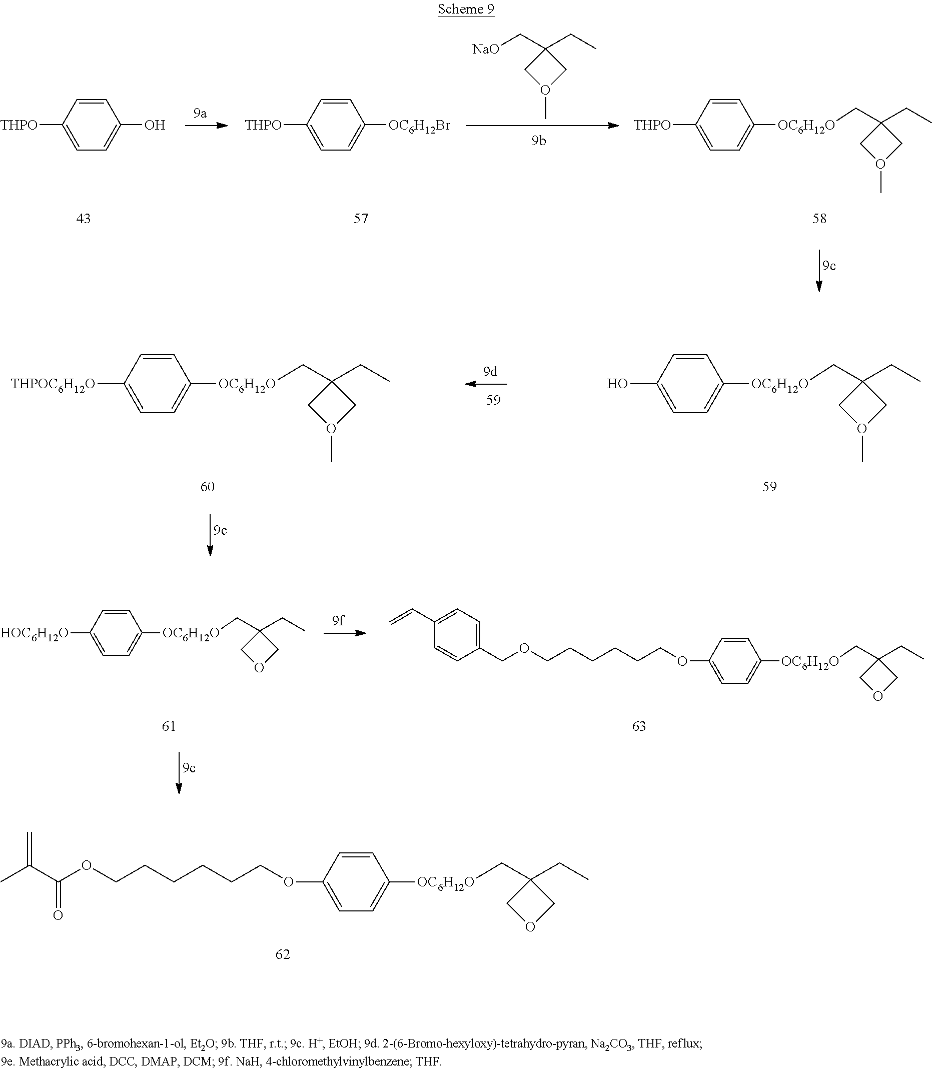

Other suitable co-monomers include compounds comprising an ethylene oxide linker such as, but are not limited to, compounds of the following formulae:

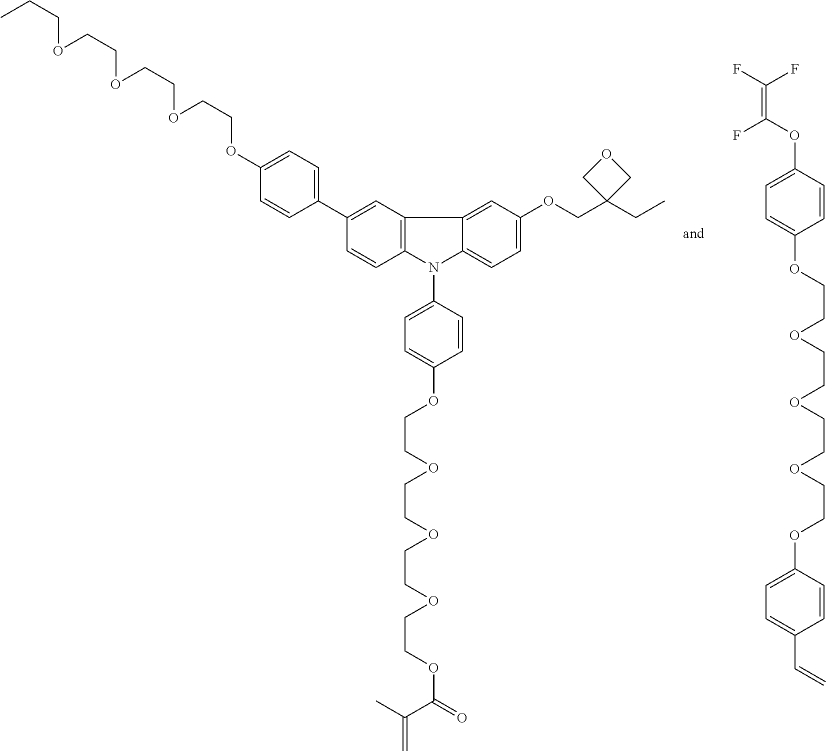

Additional objects, advantages, and novel features of this invention will become apparent to those skilled in the art upon examination of the following examples thereof, which are not intended to be limiting. In the Examples, procedures that are constructively reduced to practice are described in the present tense, and procedures that have been carried out in the laboratory are set forth in the past tense.

### EXAMPLES

Schemes 10 through 13 provide methods for producing some of the co-monomers that can be used to modify the electronic property of the resulting polymer.

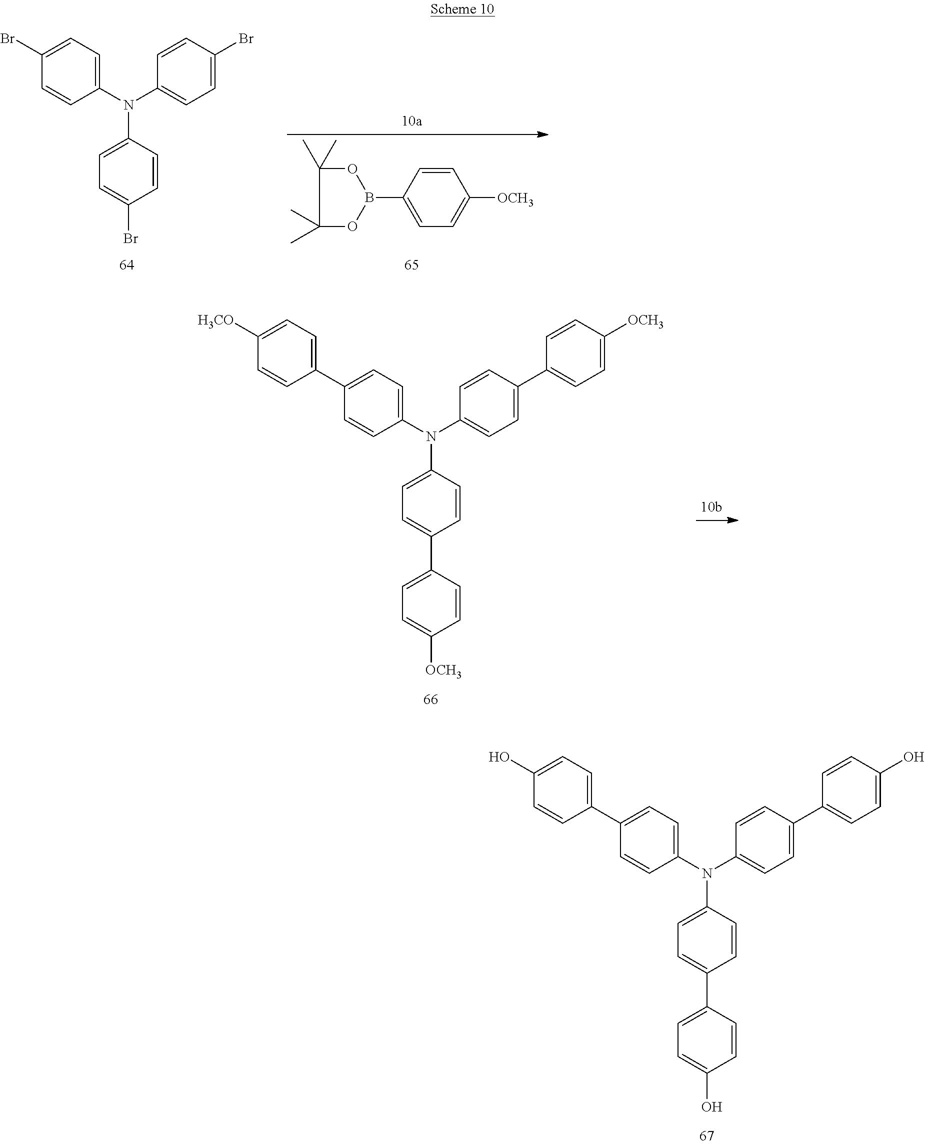

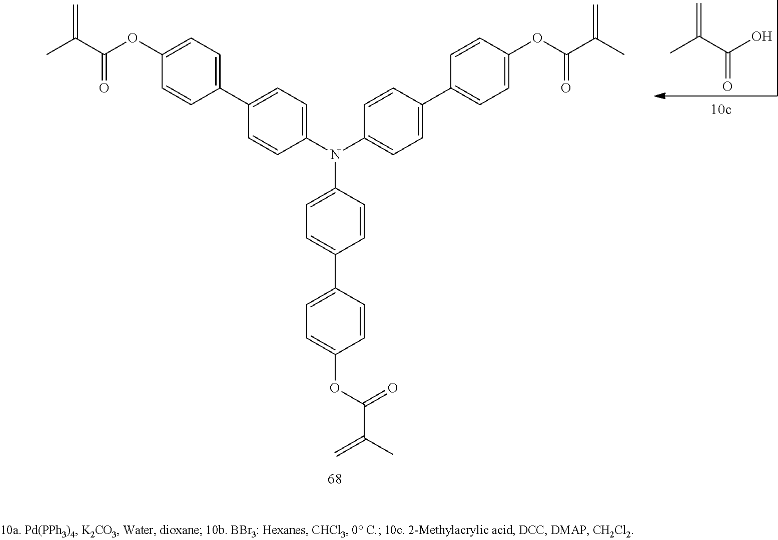

### Preparation of tris-(4′-methoxybiphenyl-4-yl)-amine (66)

A suspension of tris(4-bromophenyl)-amine (0.963 g, 2.00 mmol), 2-(4-methoxyphenyl)-4,4,5,5-tetramethyl-[1,3,2]dioxaborolane (1.450 g, 6.00 mmol), palladium tetrakistriphenylphosphine(0) [Pd(PPH₃)₄] (0.347 g, 0.30 mmol) and potassium carbonate (K₂CO₃) (1.66 g, 12.0 mmol in 3.0 cm³ of water) in dioxane (4.0 cm³) was heated under reflux under an atmosphere of dry nitrogen for 24 h. The reaction mixture was cooled to room temperature, washed with water and extracted into diethyl ether (3×25 cm³). The organic extracts were combined, washed with brine, dried (MgSO₄), concentrated in vacuuo and the residues purified by column chromatography [silica gel, eluted with hexane:dichloromethane (DCM), 1:1] to provide a dark red solid, which was re-crystallized from ethyl acetate and ethanol. Yield 0.69 g 61%. ¹H NMR (500 MHz, CDCl₃) δ/ppm: 3.73 (s, 9H, —CH₃), 6.52 (d of t, 6H, aromatic), 6.83 (d of t, 6H aromatic) 7.23 (d of t, 6H, aromatic) and 7.37 (d of t, 6H, aromatic).

### Preparation of tris-(4′-hydroxybiphenyl-4-yl)-amine (67)

A cooled (0° C.) solution of boron tribromide (3.672 cm³, 3.672 mmol, 1.0 M solution in hexanes) was added dropwise to a stirred, cooled (0° C.) solution of compound 66 (0.690 g, 1.224 mmol) in 15 cm³ of dichloromethane (DCM) under an atmosphere of dry nitrogen. The reaction mixture was allowed to warm slowly to room temperature and stirred for 20 h. The reaction was quenched via dropwise addition of hydrochloric acid (HCl) (20 cm³, 10%), diluted with DCM (50 cm³), neutralized via the addition of saturated sodium carbonate (Na₂CO₃) solution in water (100 cm³) and the organic layer was extracted with diethyl ether (Et₂O) (3×30 cm³). The combined extracts were combined, washed with brine, dried (MgSO₄), concentrated in vacuuo and the resulting residues purified by column chromatography [silica gel eluted with DCM] providing a dark yellow solid, which was re-crystallized from ethyl acetate and ethanol to yield yellow crystals. Yield 0.50 g, 78%. ¹H NMR (500 MHz, CDCl₃) δ/ppm: 5.0 (s, 3H, —OH), 6.52 (d of t, 6H, aromatic), 6.79 (d of t, 6H aromatic) 7.23 (d of t, 6H, aromatic) and 7.31 (d of t, 6H, aromatic).

### Preparation of 2-ethylacrylic acid 4′-{bis-[4′-(2-methyl-acryloyloxy)-biphenyl-4-yl]-amino}-biphenyl-4-yl ester (68)

A solution of compound 67 (0.48 g, 0.927 mmol), 1,3-dicyclohexylcarbodiimide (DCC) (0.59 g, 2.860 mmol), 4-dimethylaminopyridine (DMAP) (3.49 mg, 0.286 mmol) and 2-methyl-acrylic acid (0.242 cm³, 2.86 mmol) in DCM:Et2O (5.0 cm³, 3:2) was stirred at room temperature for 24 h. The reaction mixture was filtered, the solvent removed in vacuuo and the residues purified by column chromatography [silica gel, eluted with DCM:hexanes, 1:1] providing a yellow solid, which was used without further purification. Yield 0.43 g, 65%. ¹H NMR (500 MHz, CDCl₃) δ/ppm: 1.93 (s, 9H, —CH₃), 5.49 (d, 3H, —C═CH₂), 5.98 (d, 3H, —C═CH₂), (6.52 (d of t, 6H, aromatic), 7.13 (d of t, 6H aromatic) 7.23 (d of t, 6H, aromatic) and 7.45 (d of t, 6H, aromatic).

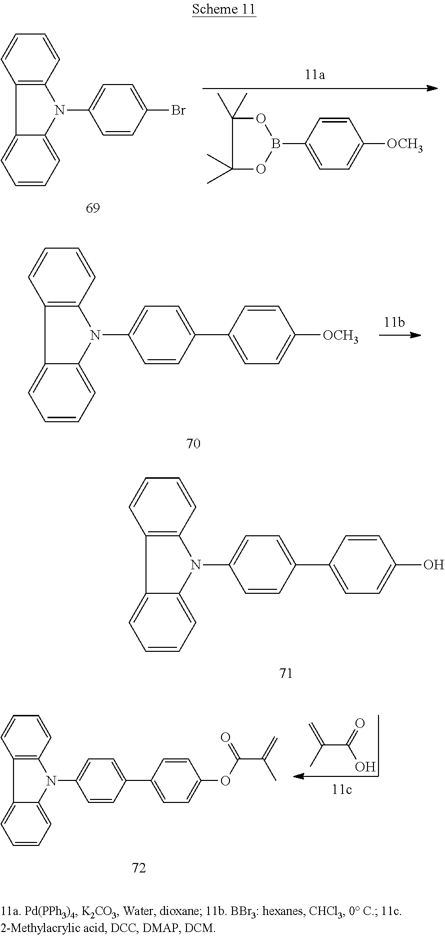

### Preparation of 9-(4′-methoxybiphenyl-4-yl)-9H-carbazole (70)

A suspension of 9-(4-bromophenyl)-9H-carbazole (1.933 g, 6.00 mmol), compound 69 (1.45 g 6.00 mmol), Pd(PPh₃)₄ (0.693 g, 0.60 mmol) and K₂CO₃ (1.66 g, 12.0 mmol in 10 cm³ of water) in 10 cm³ of dioxane was heated under reflux under an atmosphere of dry nitrogen for 24 h. The reaction mixture was cooled to room temperature, washed with water and extracted with diethyl ether (3×20 cm³). The organic extracts were combined, washed with brine, dried (MgSO₄), concentrated in vacuuo and the residues purified by column chromatography [silica gel, eluted with hexane:DCM, 1:1] providing a dark yellow solid, which was re-crystallized from ethyl acetate and ethanol. Yield 1.53 g 73%. ¹H NMR (500 MHz, CDCl₃) δ/ppm: 3.73 (s, 3H, —CH₃), 6.83 (d, 2H, aromatic) and 7.0 to 7.55 (m, 14H aromatic).

### Preparation of 4′-carbazol-9-yl-biphenyl-4-ol (71)

A cooled (0° C.) solution of boron tribromide (1.92 cm³, 1.92 mmol, 1.0 M solution in hexanes) was added dropwise to a stirred, cooled (0° C.) solution of compound 70 (0.67 g, 1.92 mmol) in 15 cm³ of DCM under an atmosphere of dry nitrogen. The reaction mixture was allowed to warm slowly to room temperature and stirred for 20 h. The reaction was quenched via the dropwise addition of HCl (20 cm³, 10%), diluted with 50 cm³ of DCM, neutralized via the addition of saturated sodium carbonate (Na₂CO₃) solution in water (100 cm³) and the organic layer was extracted with Et₂O (3×30 cm³). The combined extracts were washed with brine, dried (MgSO₄), concentrated in vacuuo and the residues purified by column chromatography [silica gel eluted with DCM] providing a dark yellow solid, which was re-crystallized from ethyl acetate and ethanol providing yellow crystals. Yield 0.52 g, 81%. ¹H NMR (500 MHz, CDCl₃) δ/ppm: 5.0 (s, 1H, —OH), 6.79 (d, 2H, aromatic) and 7.0 to 7.55 (m, 14H aromatic).

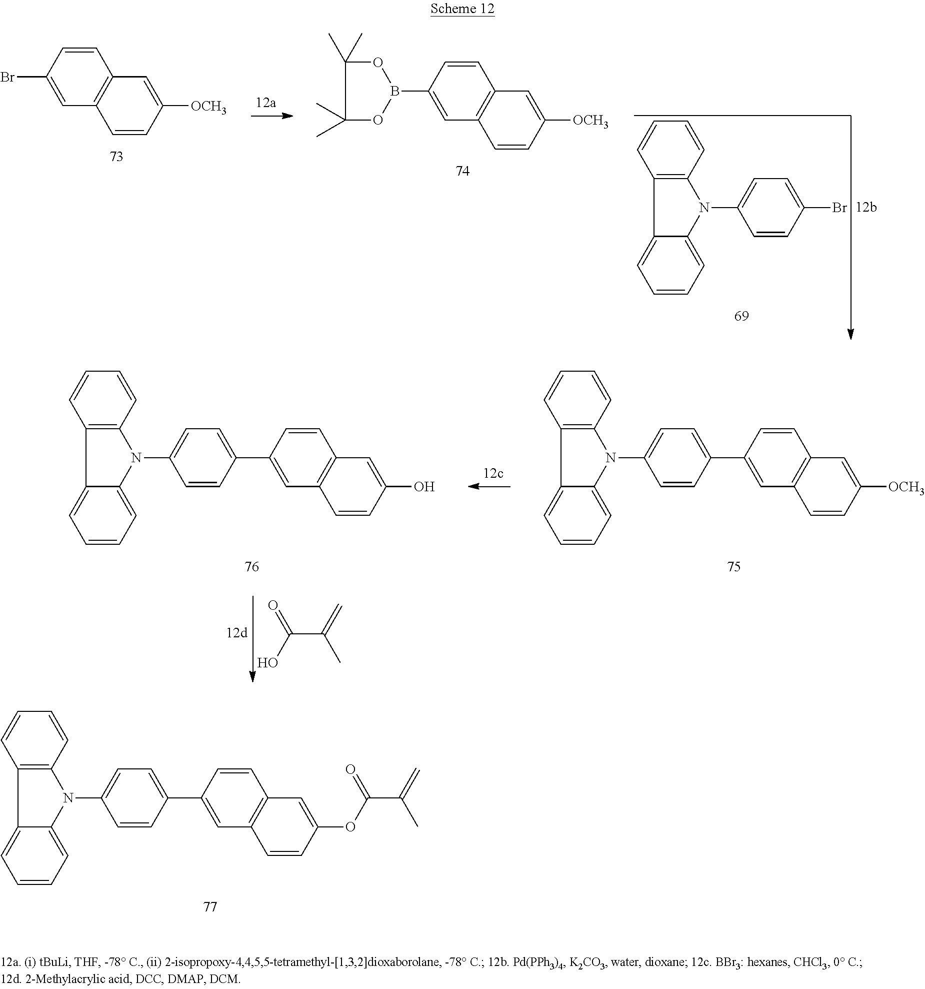

### Preparation of 2-(6-methoxynaphthalen-2-yl)-4,4,5,5-tetramethyl-[1,3,2]dioxaborolane (74)

A solution of t-butyl lithium (11.76 cm³, 20.0 mmol, 1.7 M in hexanes) was added to a stirred, cooled (−78° C.) solution of 2-bromo-6-methoxynaphthalene (2.371 g, 10.00 mmol) in dry THF (20 cm³) under an atmosphere of dry nitrogen. The reaction mixture was maintained at −78° C. for 3 h and 2-isopropoxy-4,4,5,5-tetramethyl-[1,3,2]dioxaborolane (4.08 cm³, 20.00 mmol) was added dropwise. The cold bath was removed and the reaction mixture allowed to warm to room temperature overnight. The reaction mixture was washed with water and extracted with DCM (3×25 cm³). The combined organic layers were washed with brine, dried (MgSO₄), concentrated in vacuuo and the residues purified by column chromatography [silica gel, eluted with hexane:ethyl acetate. 4:1] providing a white solid, which was used without further purification. Yield 2.44 g, 86%. ¹H NMR (500 MHz, CDCl₃) δ/ppm: 1.26 (s, 12H, —CH₃), 3.73 (s, 3H, —CH₃), 7.0 (d of d, 2H, aromatic), 7.3 (d of d, 1H aromatic) and 7.6 (m 3H, aromatic).

### Preparation of 9-[4-(6-methoxynaphthalen-2-yl)-phenyl]-9H-carbazole (75)

A suspension of compound 74 (0.853 g, 3.00 mmol), compound 69 (0.967 g 3.00 mmol), Pd(PPh₃)₄ (0.347 g, 0.30 mmol) and K₂CO₃ (0.880 g, 6.00 mmol in 5.0 cm³ of water) in dioxane (5.0 cm³) was heated under reflux under an atmosphere of dry nitrogen for 24 h. The reaction mixture was cooled to room temperature, washed with water and extracted with DCM (3×20 cm³). The organic extracts were combined, washed with brine, dried (MgSO₄), concentrated in vacuuo and the residue was purified by column chromatography [silica gel, eluted with hexane:DCM, 40:60] providing a pale yellow solid, which was re-crystallized from ethyl acetate and ethanol. Yield 0.91 g 76%. ¹H NMR (500 MHz, CDCl₃) δ/ppm: 3.73 (s, 3H, —CH₃), 6.97 (d of d, 1H, aromatic) and 7.04 (m, 17H aromatic).

### Preparation of 6-(4-carbazol-9-yl-phenyl)-naphthalen-2-ol (76)

A cooled (0° C.) solution of boron tribromide (2.00 cm³, 2.00 mmol, 1.0 M solution in hexanes) was added dropwise to a stirred, cooled (0° C.) solution of compound 75 (0.798 g, 2.00 mmol) in 15 cm³ of DCM under an atmosphere of dry nitrogen. The reaction mixture was allowed to warm slowly to room temperature and stirred for 20 h. The reaction was quenched via dropwise addition of HCl (25 cm³, 10%), diluted with DCM (50 cm³), neutralized via the addition of saturated sodium carbonate (Na₂CO₃) solution in water (100 cm³) and the organic layer was extracted with DCM (3×30 cm³). The extracts were combined, washed with brine, dried (MgSO₄), concentrated in vacuuo and the residue was purified by column chromatography [silica gel eluted with DCM] providing a yellow solid, which was re-crystallized from ethyl acetate and ethanol providing yellow crystals. Yield 0.75 g, 97%. ¹H NMR (500 MHz, CDCl₃) δ/ppm: 5.0 (s, 1H, —OH), 6.97 (d of d, 2H, aromatic) and 7.00 to 7.85 (m, 16H aromatic).

### Preparation of 2-methylacrylic acid 6-(4-carbazol-9-yl-phenyl)-naphthalen-2-yl ester (77)

A solution of compound 76 (0.385 g, 1.00 mmol), DCC (0.21 g, 1.00 mmol), 4-DMAP (0.12 mg, 0.100 mmol) and 2-methyl-acrylic acid (0.085 cm³, 1.00 mmol) in DCM:Et₂O (5.0 cm³, 1:1) was stirred at room temperature for 24 h. The reaction mixture was filtered, concentrated in vacuuo and the residue was purified by column chromatography [silica gel, eluted with DCM:hexanes, 1:1] providing a yellow solid, which was used without further purification. Yield 0.39 g, 86%. ¹H NMR (500 MHz, CDCl₃) δ/ppm: 1.93 (s, 3H, —CH₃), 5.49 (d, 1H, —C═CH₂), 5.98 (d, 1H, —C═CH₂) and 6.97 to 7.85 (m, 18H, aromatic).

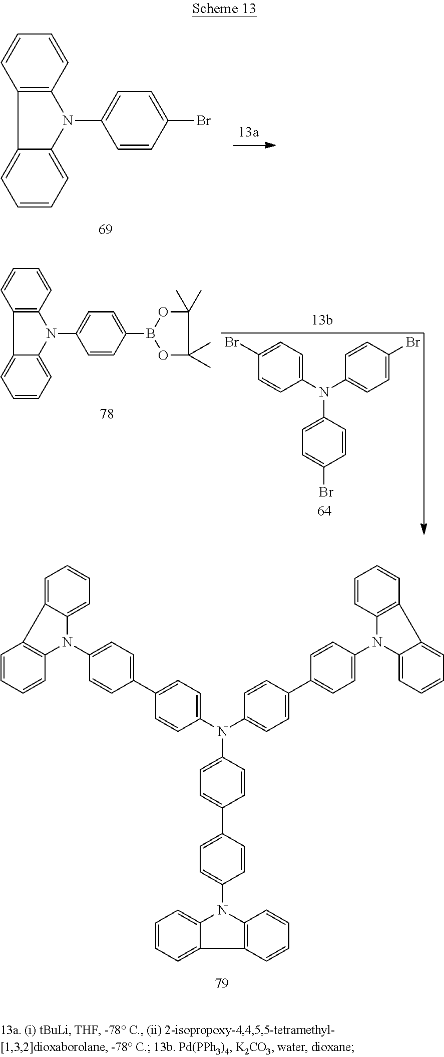

### Preparation of 9-[4-(4,4,5,5-tetramethyl-[1,3,2]dioxaborolan-2-yl)-phenyl]-9H-carbazole (78)

A solution of t-butyl lithium (5.88 cm³, 10.00 mmol, 1.7 M in hexanes) was added to a stirred, cooled (−78° C.) solution of compound 69 (1.611 g, 5.00 mmol) in dry THF (20 cm³) under an atmosphere of dry nitrogen. The reaction mixture was maintained at −78° C. for 3 h and 2-isopropoxy-4,4,5,5-tetramethyl-[1,3,2]dioxaborolane (1.02 cm³, 5.00 mmol) was added dropwise. The cold bath was removed and the reaction mixture allowed to warm to room temperature overnight. The reaction mixture was washed with water and extracted with DCM (3×25 cm³). The organic layers were combined, washed with brine, dried (MgSO₄) and concentrated in vacuuo. The residue was purified by column chromatography [silica gel, eluted with hexane:ethyl acetate. 4:1] providing a white solid, which was used without further purification. Yield 1.70 g, 92%. ¹H NMR (500 MHz, CDCl₃) δ/ppm: 1.26 (s, 12H, —CH₃) and 7.0 to 7.55 (m, 12H, aromatic).

### Preparation of tris-(4′-carbazol-9-yl-biphenyl-4-yl)-amine (79)

A suspension of compound 78 (0.250 g, 0.677 mmol), compound 69 (0.105 g 0.218 mmol), Pd(PPh₃)₄ (39.30 mg, 0.03 mmol) and K₂CO₃ (0.187 g, 1.354 mmol in 2.0 cm³ of water) in dioxane (3.0 cm³) was heated under reflux under an atmosphere of dry nitrogen for 24 h. The reaction mixture was cooled to room temperature, washed with water and extracted with DCM (3×15 cm³). The organic extracts were combined, washed with brine, dried (MgSO₄), concentrated in vacuuo and the residue was purified by column chromatography [silica gel, eluted with hexane:DCM, 1:61] providing a pale yellow solid, which was re-crystallized from ethyl acetate and ethanol. Yield 0.146 g, 69% based on compound 69. ¹H NMR (500 MHz, CDCl₃) δ/ppm: 6.52 (d of d, 6H, aromatic) and 7.08 to 7.55 (m, 42H aromatic).

There are a wide variety of methods for cross-linking compounds of the invention, e.g., thermally, photolytically, and chemically including using radical initiators. Typically, the method of cross linking is determined by the nature of the cross linking functional group. In some instances, a linker can be added to provide cross-linking between molecules of the invention. Such linker can have two or more complementary functional groups such that it will react with the cross-linking functional group of compounds of the invention. Schemes 14 through 17 provide examples of some of the various methods available for the polymerization and cross-linking processes.

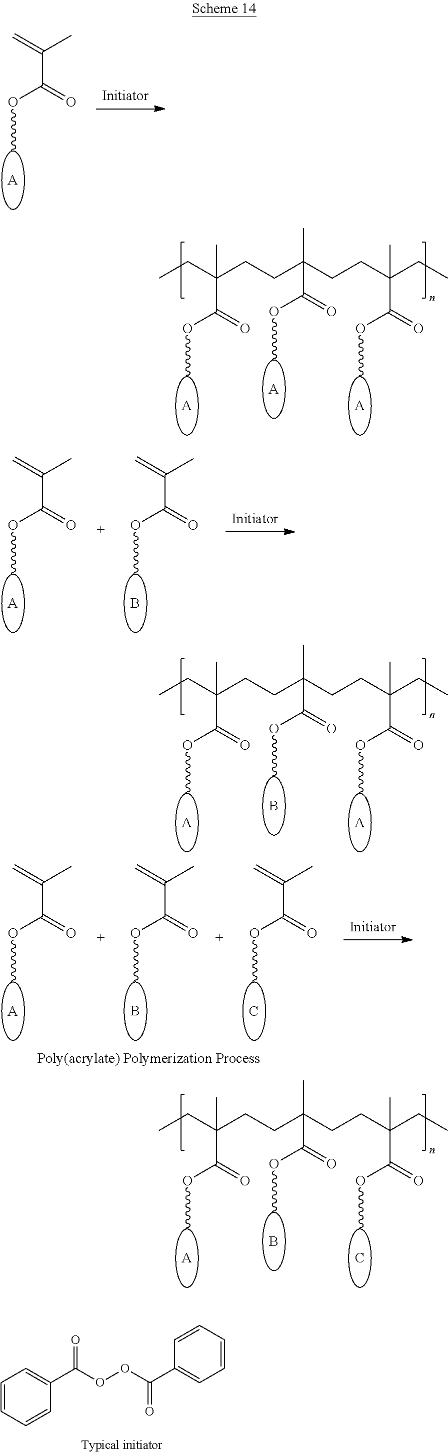

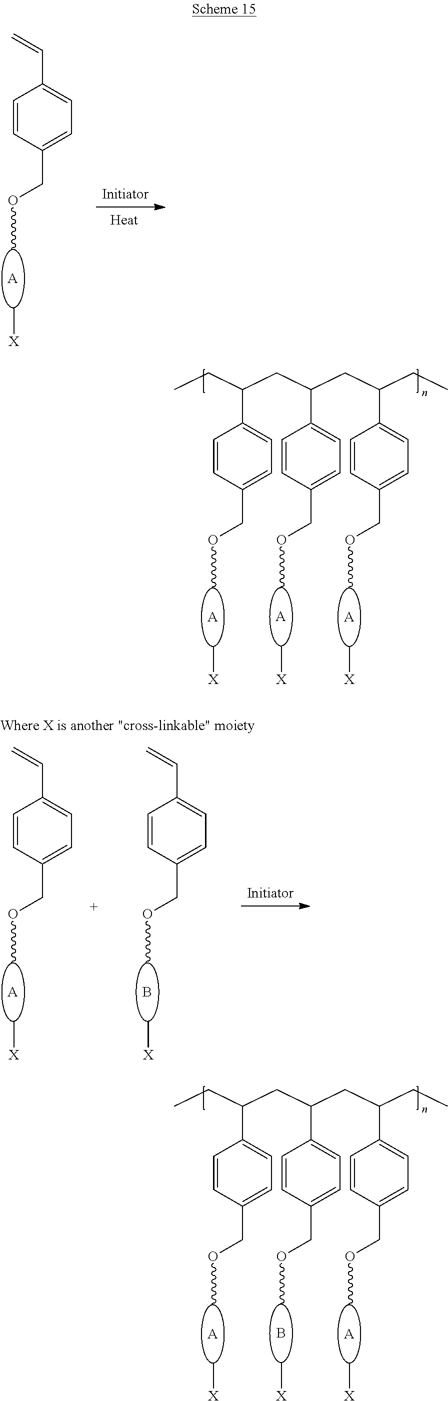

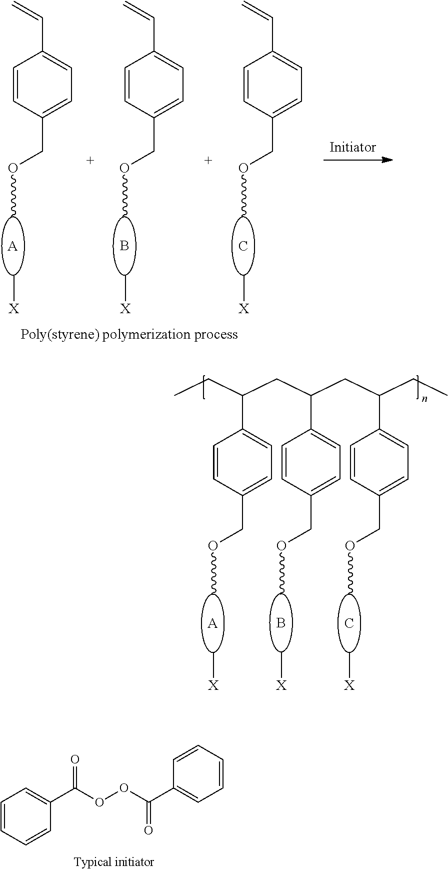

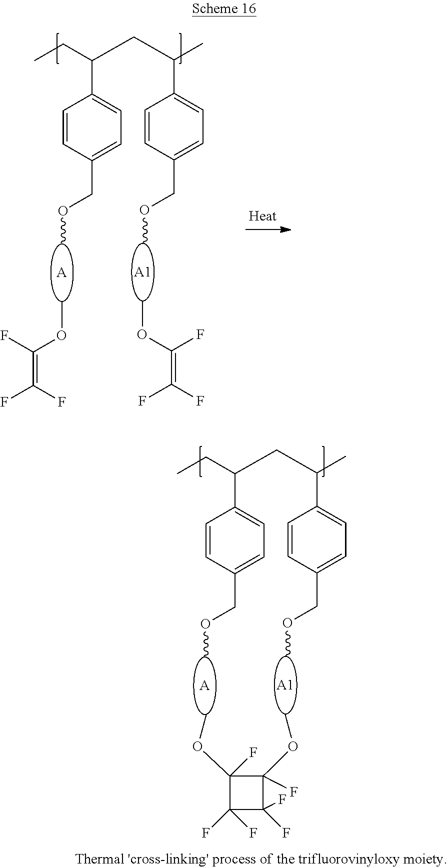

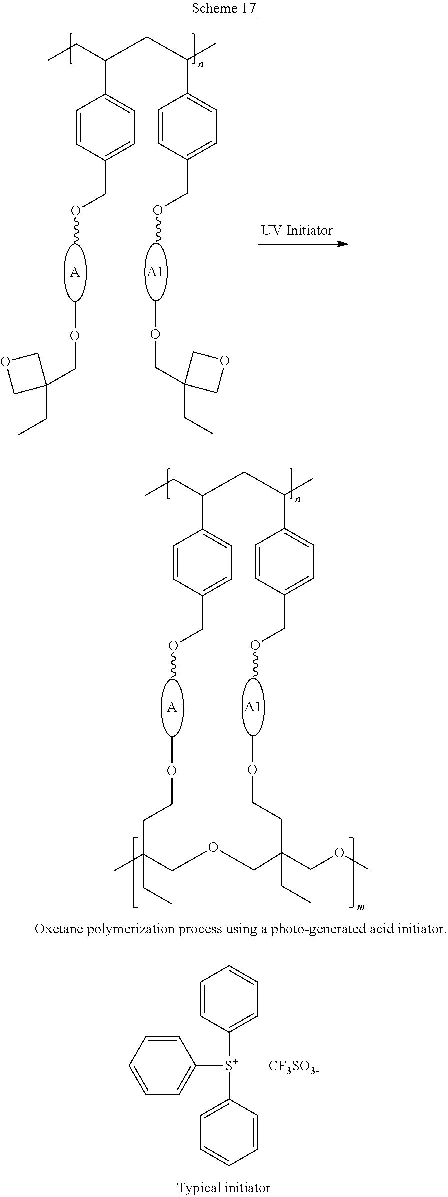

### Example of the Polymerization Process

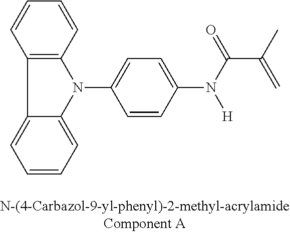

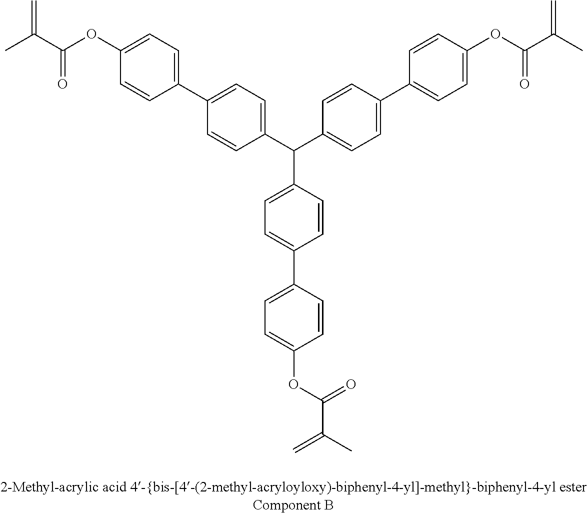

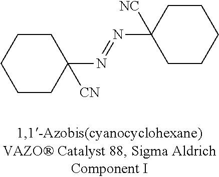

| Solvent and Volume | Component A | Component B | Component I | Ref. |
|---|---|---|---|---|
| N-Methyl-2-pyrrolidone | 0.6626 g | 73.70 mg | 49.60 mg | 10% |
| (NMP) 4.0 cm³ | 2.030 mmol | 0.1015 mmol | 0.2030 mmol | |
| NMP 4.0 cm³ | 0.3313 g | 73.7 mg | 24.80 mg | 5% |
| | 1.015 mmol | 0.1015 mmol | 0.1015 mmol | |

The above solutions were adjusted to 5.0, 10.0, 20, 30 and 41.0 mg cm⁻³ and drop cast onto suitable substrates and spun at 3000 rpm for 60 s with a 1.0 s ramp rate. The substrates were then placed on a hot plate at 125° C. for 40 min under an atmosphere of dry nitrogen.

A multilayer OLED was fabricated using a combination of solution processing and chemical vapor deposition (CVD). The structure of this stack was indium tin oxide (ITO), PEDOT:PSS (31.80 nm), cross-linked polymer (34.63 nm), green emitting QDs (7.00 nm diameter, nominally three layers), 2,2′,2″-(1,3,5-Benzinetriyl)-tris(1-phenyl-1-H-benzimidazole) (TPBi) (40.00 nm), LiF (1.50 nm) and a cathode comprising Al.

ITO-coated glass was cleaned thoroughly by sonication in a 2% Tergitol solution, followed by a rinsing in de-ionized water and immersion for 10 minutes in a 5:1:1 solution of DI water:ammonium hydroxide:hydrogen peroxide heated to 70° C. Substrates were then rinsed with deionized (DI) water and sonicated in acetone and methanol for 15 minutes each. After drying with nitrogen, they were cleaned with UV/ozone. Spin-coating of PEDOT:PSS, the monomer solution and QD layers was performed in a nitrogen-filled glove box. A 3:5 solution (0.3 cm³) of Baytron P® in methanol was cast onto the ITO substrate. After the solution had completely wet the surface, the substrate was accelerated to 3000 rpm for 1 second, then to 6000 rpm and held at that rate for 30 seconds. The film was annealed on a hotplate inside the glove box at 125° C. for 1 h. After annealing, the substrate was placed on the spin-coater, and a 20 mg cm⁻³ solution (0.3 cm³) of monomer/initiator solution in NMP was dropped onto the substrate surface. The substrate was accelerated to 3000 rpm and held at this rate for 60 seconds. The resultant film was annealed at 125° C. for 40 minutes. A solution of 3.0 mg cm⁻³ of QDs in octane was cast onto the surface of the substrate. The substrate was spun at 4000 rpm for one minute. Any suitable QD including, but not limited to, those described in US Patent Publication Number 2007/0111324, which is incorporated herein by reference in its entirety, can be used. The substrate with the PEDOT:PSS/cross-linked/QD tri-layer was moved in an inert atmosphere to a vacuum chamber. A 40 nm thick layer of TPBi was deposited at a rate of 5.0 Ås⁻¹. Film deposition was carried out at a base pressure of 2×10⁻⁶ mbar. The chamber was vented and a shadow mask for depositing a patterned cathode was placed over the devices. The devices were placed back into the chamber and pumped to a base pressure of 2×10⁻⁶ mbar. A bi-layer of lithium fluoride and aluminum was deposited using thermal evaporation at a rate of about 0.1 Ås⁻¹ for LiF and about 5-25 Ås⁻¹ for Al. Finished devices were removed from the chamber and characterized under an inert atmosphere.

The device described above provided a peak current density of 630 m Amp cm⁻² at 11.5 V, a peak luminance 255 cd m⁻² at 9.2 V and a peak efficiency of 2.7 cd Amp⁻¹ at 5.2.

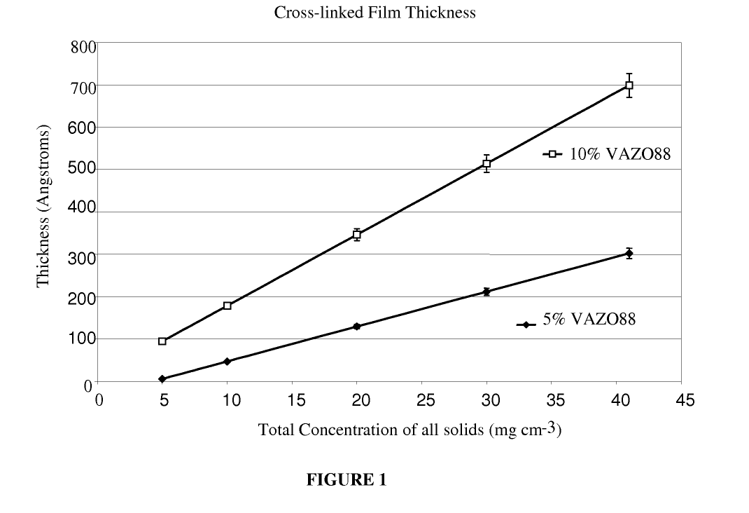

FIG. 1 shows AFM Analysis of cross-linked polymer films formed from N-(4-carbazol-9-yl-phenyl)-2-methyl-acrylamide, using VAZO88 as the catalyst in 5 and 10% relative concentrations in solutions comprising 5, 10, 20 30 and 41 mg cm⁻³ of all solids and which demonstrates the degree of control by way of film thickness that is achievable.

The foregoing discussion of the invention has been presented for purposes of illustration and description. The foregoing is not intended to limit the invention to the form or forms disclosed herein. Although the description of the invention has included description of one or more embodiments and certain variations and modifications, other variations and modifications are within the scope of the invention, e.g., as may be within the skill and knowledge of those in the art, after understanding the present disclosure. It is intended to obtain rights which include alternative embodiments to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. An electronic device comprising an organic conductive layer, wherein said organic conductive layer comprises a cross-linked polymer of a conductive material.

2. The electronic device of claim 1, wherein said electronic device is an organic light emitting diode (OLED).

3. The electronic device of claim 2, wherein said OLED is an electroluminescent OLED or an electro-phosphorescent OLED.

4. The electronic device of claim 2, wherein said conductive layer is a hole-transport layer or an electron-transport layer.

5. A method for producing an organic conductive layer in an electronic device, said method comprising:
attaching a layer of organic conductive material onto a solid substrate, wherein the organic conductive material comprises an electric conducting moiety and a cross-linkable moiety; and
cross-linking the organic conductive material to one another by subjecting the solid substrate bound organic conductive material to conditions sufficient to form cross-linkage between the solid substrate bound organic conductive materials.

6. The method of claim 5, wherein the electronic device is an organic light emitting diode (OLED).

7. The method of claim 6, wherein the organic conductive layer is a hole-transport layer or an electron-transport layer.

8. The method of claim 5, wherein the cross-linkable moiety comprises a diene, siloxane, acylate, styrene, epoxide, trifluorovinyloxy, acrylate, methacrylate, or oxetane moiety.

9. The method of claim 5, wherein said step of cross-linking the organic conductive material comprises thermal annealing, photolysis, reacting the solid substrate bound organic conductive material with a cross-linking compound, or a combination thereof.

10. A compound of the formula: 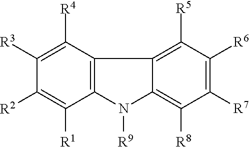
wherein
each of R¹, R², R⁴, R⁵, R⁷, and R⁸ is independently, hydrogen, alkyl, halide, nitro, cyano, —Y¹R^{a}, —NR^{a}R^{b}, or —C(═O)R^{c},
wherein
Y¹ is O or S;
each R^{a} is independently hydrogen, or alkyl;
each R^{b} is hydrogen, alkyl, or a nitrogen protecting group;
R^{c} is hydrogen, alkyl, aryl, aralkyl, or haloalkyl;
each of R³ and R⁶ is independently —XAr¹, —NAr¹R¹⁰, or a substituted aryl,
wherein
X is O or S;
R¹⁰ is hydrogen, alkyl, or an optionally substituted aryl; and
Ar¹ is a substituted aryl; and
R⁹ is a substituted aryl group comprising a cross-linkable functional group moiety, provided at least one of the aryl substituent of R³ comprises an electron withdrawing group and at least one of R⁶ or the aryl substituent comprises an electron withdrawing group or a cross-linkable functional group moiety.

11. The compound according to claim 10 of the formula: 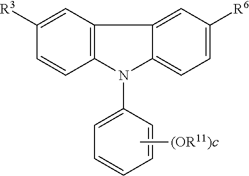
wherein
c is an integer from 1 to 3;
R³ and R⁶ are as defined in claim 10; and
R¹¹ is —R¹²—Z,
wherein
R¹² is alkylene; and
Z is —Y²R^{d}, —NR^{d}R^{e}, or a cross-linkable functional group moiety,
wherein
Y² is O or S;
each R^{d} is independently hydrogen, or alkyl; and
each R^{e} is hydrogen, alkyl, or a nitrogen protecting group.

12. The compound according to claim 11 of the formula: 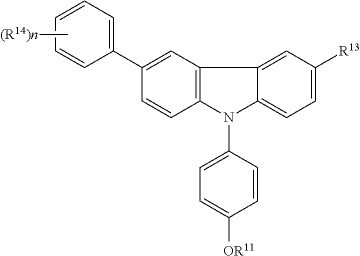
wherein
R¹¹ is as defined in claim 11; 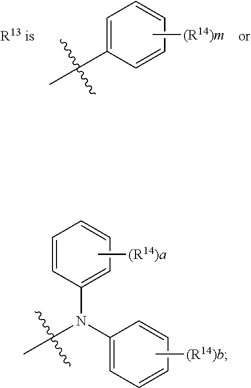
each of a, b, m, and n is independently an integer from 0 to 5; and
each R¹⁴ is independently an electron withdrawing group, or a cross-linkable functional group moiety,
provided at least one of R¹⁴ is an electron withdrawing group and at least one of R¹¹ and R¹⁴ comprises a cross-linkable functional group moiety.

13. The compound according to claim 12 of the formula: 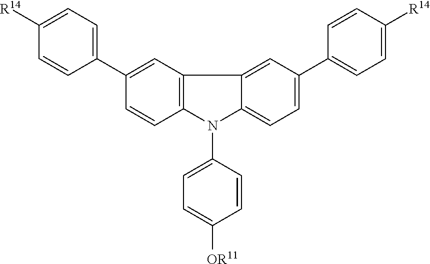
wherein
R¹¹ is as defined in claim 11; and
each R¹⁴ is independently an electron withdrawing group, or a cross-linkable functional group moiety,
provided at least one of R¹⁴ is an electron withdrawing group and at least one of R¹¹ and R¹⁴ comprises a cross-linkable functional group moiety.

14. The compound according to claim 12 of the formula: 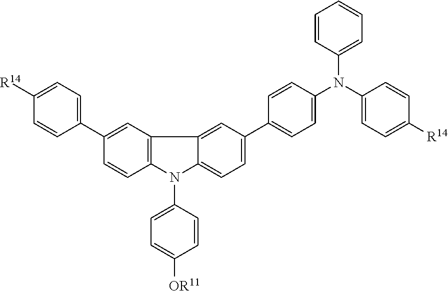
wherein
R¹¹ is as defined in claim 11; and
each R¹⁴ is independently an electron withdrawing group, or a cross-linkable functional group moiety,
provided at least one of R¹⁴ is an electron withdrawing group and at least one of R¹¹ and R¹⁴ comprises a cross-linkable functional group moiety.

15. The compound according to claim 11, wherein R¹² is C₂-C₁₂ alkylene.

16. The compound according to claim 11, wherein Z is —OH or a cross-linkable functional group moiety.

17. The compound according to claim 16, wherein the cross-linkable functional group moiety comprises a diene, siloxane, acylate, styrene, epoxide, trifluorovinyloxy, acrylate, methacrylate, or oxetane moiety.

18. A conductive polymeric layer in an electronic device, wherein said conductive polymeric layer comprises a cross-linked monomer of a compound of claim 10.

19. The conductive polymeric layer of claim 18, wherein said electronic device is an organic light emitting diode (OLED), a solar energy panel, an organic thin film transistor, or an organic radio frequency identification chip.

20. The conductive polymeric layer of claim 19, wherein the electronic device is an OLED.

21. The conductive polymeric layer of claim 20, wherein said OLED is a small molecule electroluminescent OLED, a small molecule electro-phosphorescent OLED, a polymer OLED, a quantum dot OLED or a combination thereof.

22. The conductive polymeric layer of claim 20, wherein said conductive polymeric layer is a hole-transport layer or an electron-transport layer.
